(19) United States
(12) Patent Application Publication
(10) Pub. No.: US 2018/0314102 A1
(43) Pub. Date: Nov. 1, 2018

(54) LIGHTING DEVICE

(71) Applicant: FUJIFILM Corporation, Tokyo (JP)

(72) Inventors: Hirofumi TOYAMA, Kanagawa (JP); Ryo SATAKE, Kanagawa (JP); Takashi YONEMOTO, Kanagawa (JP); Tatsuya OBA, Kanagawa (JP); Natsuru CHIKUSHI, Kanagawa (JP)

(73) Assignee: FUJIFILM Corporation, Tokyo (JP)

(21) Appl. No.: 16/012,340

(22) Filed: Jun. 19, 2018

Related U.S. Application Data
(63) Continuation of application No. PCT/JP2016/087770, filed on Dec. 19, 2016.

(30) Foreign Application Priority Data
Dec. 22, 2015 (JP) 2015-250683
Jan. 29, 2016 (JP) 2016-016095

(51) Int. Cl. G02F 1/1347; G02F 1/1335; H01L 33/50

(52) U.S. Cl. CPC G02F 1/13473; G02F 1/133611; G02F 2001/1351; H01L 33/505; G02F 1/133603

(57) ABSTRACT

There is provided a lighting device using a wavelength conversion sheet used in a liquid crystal display or the like, and an object of the invention is to provide a lighting device having satisfactory durability. The object is achieved by a lighting device including: a point light source; a wavelength conversion sheet; and a light intensity reduction member arranged between the point light source and the wavelength conversion layer, in which the light intensity reduction member reduces peak illuminance of light that is applied by the point light source on a light incident surface of a wavelength conversion sheet by 10% to 80%, and absorbance of light having a wavelength of 450 nm measured by using an integrating sphere is less than 5%.

### CROSS-REFERENCE TO RELATED APPLICATIONS

This application is a Continuation of PCT International Application No. PCT/JP2016/087770 filed on Dec. 19, 2016, which claims priority under 35 U.S.C. § 119(a) to Japanese Patent Application No. 2015-250683 filed on Dec. 22, 2015 and Japanese Patent Application No. 2016-016095 filed on Jan. 29, 2016. Each of the above applications is hereby expressly incorporated by reference, in its entirety, into the present application.

### BACKGROUND OF THE INVENTION

### 1. Field of the Invention

The present invention relates to a lighting device used for a backlight or the like of a liquid crystal display device.

### 2. Description of the Related Art

A liquid crystal display device (hereinafter, referred to as an LCD) expands applications thereof as an image display device that has low power consumption and saves spaces. In the recent liquid crystal display device, as the improvement in LCD performance, further power saving, the improvement in color reproducibility, and the like are required. LCD is an abbreviation of a liquid crystal display.

Along with power saving of an LCD backlight, it is known to use a wavelength conversion member for converting the wavelength of incidence rays in order to increase light utilization efficiency and to improve color reproducibility. As the wavelength conversion member, a wavelength conversion member using a quantum dot is known.

Quantum dots are crystals in the state of electrons in which the movement direction is restricted in all three dimensions, and in a case where nanoparticles of a semiconductor are three-dimensionally surrounded by a high potential barrier, the nanoparticles are quantum dots. The quantum dot exhibits various quantum effects. For example, a “quantum size effect” in which a state density (energy level) of electrons is discrete is exhibited. According to this quantum size effect, absorption wavelength and emission wavelength of light may be controlled by changing the size of quantum dots.

For example, JP2015-156464A discloses a lighting device (light emitting device) used for a direct type backlight or the like including light sources, a light diffusing member that covers a plurality of light sources in common, and wavelength conversion members that are arranged in regions corresponding to respective light sources and that use quantum dots converting first wavelength light from the light sources to second wavelength light, and the like.

JP2015-156464A also discloses using a blue light emitting diode (LED) as a light source.

### SUMMARY OF THE INVENTION

Recently, there is a strong demand for minimizing of display devices such as an LCD. In the backlight device using the wavelength conversion member, the distance between the light source and the wavelength conversion member is short.

However, the wavelength conversion member is easily damaged by light or heat in many cases, and the wavelength conversion member is deteriorated with the lapse of time due to heat and light from the light source. Particularly, in a case where an LED or the like is used as a light source, the light source generates much heat, has high illuminance of light, and thus the wavelength conversion member is significantly deteriorated.

Therefore, the lighting device using a wavelength conversion member in the related art has a problem in that light having an intended intensity of light may not be applied to the entire surface in the plane direction due to the use for a long period of time.

The purpose of the present invention is to solve the problems in the related art and to provide a lighting device that prevents deterioration of a wavelength conversion layer due to light and heat from a light source, has high durability, and has a long lifespan.

In order to solve the present invention, there is provided a lighting device including: one or more point light source; a wavelength conversion member; and one or more light intensity reduction members arranged between the point light source and the wavelength conversion member,

in which the light intensity reduction member reduces peak illuminance of light that is applied by the point light source on a light incident surface of the wavelength conversion member by 10% to 80%, and absorbance of light having a wavelength of 450 nm measured by using an integrating sphere is less than 5%.

In the lighting device of the present invention, the light intensity reduction member preferably reduces the illuminance of light incident to the wavelength conversion member by diffusion or total surface reflection.

It is preferable that a total area of the light intensity reduction member is 0.1% to 80% of an area of the light incident surface of the wavelength conversion member.

It is preferable that a distance between the wavelength conversion member and the light intensity reduction member is less than 50% of a distance between the point light source and the wavelength conversion member.

It is preferable that the light intensity reduction member comes into contact with the wavelength conversion member.

It is preferable that the point light source is a blue light emitting diode.

It is preferable to further comprise a light reflecting surface aside of the point light source opposite to the light intensity reduction member of the point light source.

According to the present invention, it is possible to provide the lighting device having a wavelength conversion layer used in a backlight or the like of a liquid crystal display device, in which deterioration of a wavelength conversion layer due to light and heat from a light source is prevented, which has high durability and which has a long lifespan.

### BRIEF DESCRIPTION OF THE DRAWINGS

FIG. 1 is a diagram conceptually illustrating an example of a lighting device of the present invention.

FIG. 2 is a diagram conceptually illustrating an example of the wavelength conversion member used in a lighting device of the present invention.

FIG. 3 is a diagram conceptually illustrating an action of the light intensity reduction member in a lighting device of the present invention.

FIG. 4 is a diagram conceptually illustrating a method of measuring peak illuminance reduction rate according to the present invention.

FIG. 5 is a diagram conceptually illustrating a method of measuring a peak illuminance reduction rate according to the present invention.

FIG. 6 is a diagram conceptually illustrating another example of the lighting device of the present invention.

FIG. 7 is a diagram conceptually illustrating still another example of the lighting device of the present invention.

FIG. 8 is a diagram conceptually illustrating another example of the light intensity reduction member used in the lighting device of the present invention.

### DESCRIPTION OF THE PREFERRED EMBODIMENTS

Hereinafter, the lighting device of the present invention is specifically described based on a suitable example illustrated in the accompanying drawings.

The following description of constituent elements may be made based on a representative embodiment of the present invention, but the present invention is not limited to the embodiment.

According to the present specification, the numerical range expressed by using “to” means a range including numerical values described before and after “to” as a lower limit value and an upper limit value.

In the present specification, the expression “(meth)acrylate” means any one or both of acrylate and methacrylate. The same is applied to “(meth)acryloyl” and the like.

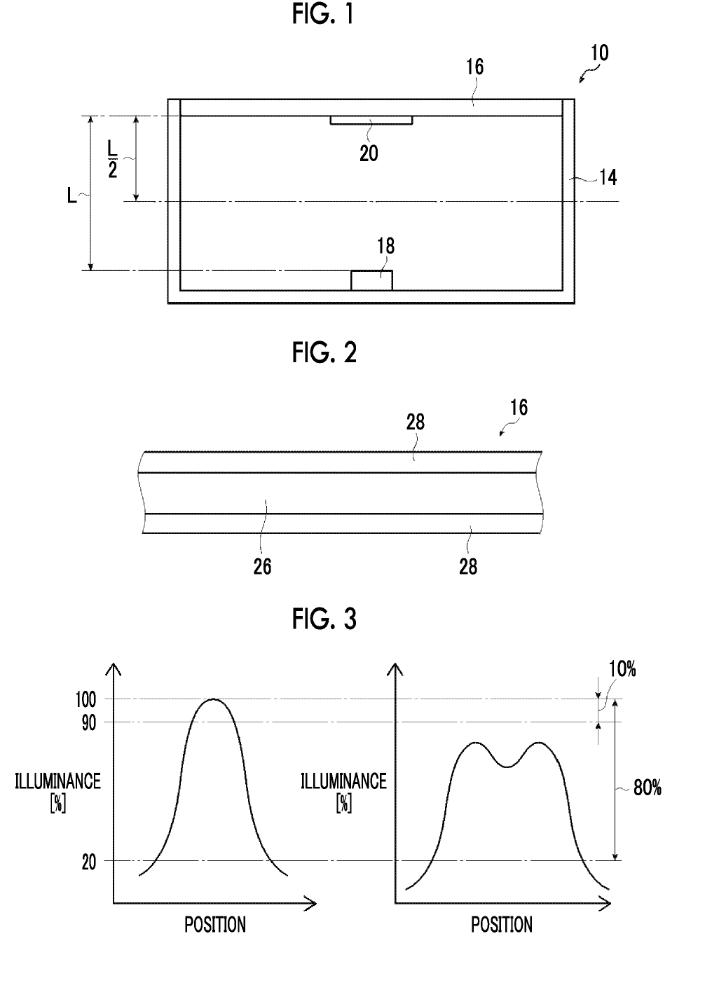

An example of a lighting device of the present invention is conceptually illustrated in FIG. 1.

A lighting device 10 is a direct-type planar lighting device used in a backlight or the like of the liquid crystal display device, and basically includes a housing 14, a wavelength conversion sheet 16 as a wavelength conversion member, a point light source 18, and a light intensity reduction member 20.

In the description below, a “liquid crystal display device” is also referred to as an LCD, and the “point light source 18” is also referred to as the “light source 18”.

FIG. 1 is merely a schematic view. Accordingly, in addition to the members shown in the drawing, the lighting device 10 may include various known members provided in known lighting devices such as an LCD backlight, for example, one or more of an LED substrate, wiring, and a heat dissipating mechanism.

For example, the housing 14 is a rectangular housing of which the maximum surface is open, and the wavelength conversion sheet 16 is arranged so as to close the open surface. The housing 14 is a well-known housing used for a backlight unit of an LCD or the like.

As a preferred embodiment, with respect to the housing 14, at least the bottom surface that is the installation surface of the point light source 18 is a light reflecting surface selected from a mirror surface, a metal reflecting surface, a diffuse reflecting surface, and the like. It is preferable that the entire inner surface of the housing 14 is a light reflecting surface.

The wavelength conversion sheet 16 is a well-known wavelength conversion sheet to which the light applied by the light source 18 is incident, in which the wavelength conversion is performed, and in which emission is performed.

A configuration of the wavelength conversion sheet 16 is conceptually illustrated in FIG. 2. The wavelength conversion sheet 16 has a wavelength conversion layer 26 and a supporting film 28 that sandwiches and supports the wavelength conversion layer 26.

For example, the wavelength conversion layer 26 is a fluorescent layer obtained by dispersing a large number of phosphors in a matrix of a curable resin or the like and has a function of converting the wavelength of light incident on the wavelength conversion layer 26 and emitting the light.

For example, in a case where the blue light applied from the light source 18 is incident on the wavelength conversion layer 26,the wavelength conversion layer 26 converts the wavelength of at least a part of the blue light so as to be red light or green light by the effect of the phosphor contained inside and emits the light.

Here, the blue light is light having a light emission center wavelength in a wavelength range of 400 to 500 nm, the green light is light having a light emission center wavelength in a wavelength range of more than 500 nm and 600 nm or less, and the red light is light having a light emission center wavelength in a wavelength range of more than 600 nm and 680 nm or less.

The function of the wavelength conversion exhibited by the fluorescent layer is not limited to the configuration in which the wavelength of the blue light is converted to be the red light or the green light, and may be a configuration in which at least a part of the incidence rays is converted into light having a different wavelength.

The phosphor is excited by at least incident excitation light and emits fluorescence.

The types of kind of the phosphor contained in the fluorescent layer are not particularly limited, and various well-known phosphors may be appropriately selected according to the performance of the required wavelength conversion or the like.

Examples of such phosphors include a phosphor obtained by doping a rare earth ion to phosphoric acid salt, aluminic acid salt, metal oxides, and the like, a phosphor obtained by doping an activating ion to a semiconducting substance such as metal sulfide, metal nitride, and the like, and a phosphor using a quantum confinement effect known as quantum dots, and the like, in addition to an organic fluorescent dye and an organic fluorescent pigment. Among these, quantum dots which can realize a light source having a narrow emission spectrum width and excellent color reproducibility in a case of being used for a display and which has excellent light emission quantum efficiency are suitably used in the present invention.

That is, according to the present invention, a quantum dot layer obtained by dispersing a quantum dot in a matrix of a resin or the like is suitably used as the wavelength conversion layer 26. In the wavelength conversion sheet 16, the wavelength conversion layer 26 as a preferable aspect is a quantum dot layer.

With respect to the quantum dot, for example, paragraphs 0060 to 0066 of JP2012-169271A may be referred to, but the present invention is not limited to these. As the quantum dot, commercially available products can be used without any limitation. The emission wavelength of the quantum dot may be generally adjusted by the composition and the size of the particle.

It is preferable that the quantum dot is uniformly dispersed in the matrix, but the quantum dot may be dispersed with bias in the matrix. The quantum dot may be used singly or two or more kinds thereof may be used in combination.

In a case where two or more quantum dots are used together, two or more kinds of quantum dots having different wavelengths of the emitted light may be used.

Specifically, examples of the well-known quantum dots include a quantum dot (A) having a light emission center wavelength in a wavelength range of more than 600 nm and 680 nm or less, a quantum dot (B) having a light emission center wavelength in a wavelength range of more than 500 nm and 600 nm or less, and a quantum dot (C) having a light emission center wavelength in a wavelength range of 400 to 500 nm. The quantum dot (A) emits red light excited by excitation light, the quantum dot (B) emits green light excited by excitation light, and the quantum dot (C) emits blue light excited by excitation light.

For example, in a case where the blue light is caused to be incident to the quantum dot layer including the quantum dot (A) and the quantum dot (B) as the excitation light, white light may be realized by the red light emitted by the quantum dot (A), the green light emitted by the quantum dot (B), and the blue light passing through the quantum dot layer. Otherwise, in a case where the ultraviolet light is caused to be incident to the quantum dot layer including the quantum dots (A), (B), and (C), as the excitation light, white light may be realized by the red light emitted by the quantum dot (A), the green light emitted by the quantum dot (B), and the blue light emitted by the quantum dot (C).

As the quantum dot, a tetrapod-type quantum dot or a so-called quantum rod which has a rod shape and directivity and emits polarized light may be used.

As described above, in the wavelength conversion sheet 16, the wavelength conversion layer 26 is formed by dispersing a quantum dot or the like as a matrix of a resin or the like.

Here, as the matrix, well-known matrices used in the quantum dot layer may be used, but it is preferable to be obtained by curing the polymerizable composition (coating composition) including at least two or more polymerizable compounds. The polymerizable groups of the at least two or more polymerizable compounds which are used together may be identical to or different from each other, but the at least two or more kinds of the compounds preferably have at least one or more common polymerizable groups.

Types of the polymerizable group are not particularly limited, but a (meth)acrylate group, a vinyl group, an epoxy group, or an oxetanyl group is preferable, a (meth)acrylate group is more preferable, and an acrylate group is even more preferable.

The polymerizable compound that becomes the matrix of the wavelength conversion layer 26 preferably includes at least one of the first polymerizable compounds including monofunctional polymerizable compounds and at least one of the second polymerizable compound including polyfunctional polymerizable compounds.

Specifically, examples thereof include an aspect of including the first polymerizable compound and the second polymerizable compound as follows.

<First Polymerizable Compound>

The first polymerizable compound is a monofunctional (meth)acrylate monomer and a monomer having one functional group selected from the group consisting of an epoxy group and an oxetanyl group.

Examples of the monofunctional (meth)acrylate monomer include acrylic acid and methacrylic acid, and derivatives of these, and specific examples thereof include an aliphatic or aromatic monomer having one polymerizable unsaturated bond (meth)acryloyl group of (meth)acrylic acid in the molecule and having an alkyl group of 1 to 30 carbon atoms. Specific examples thereof include compounds, but the present invention is not limited thereto.

Examples of an aliphatic monofunctional (meth)acrylate monomer include an alkyl (meth)acrylate in which an alkyl group has 1 to 30 carbon atoms such as methyl (meth)acrylate, n-butyl (meth)acrylate, isobutyl (meth)acrylate, 2-ethylhexyl (meth)acrylate, isononyl (meth)acrylate, n-octyl (meth)acrylate, lauryl (meth)acrylate, and stearyl (meth)acrylate;

alkoxyalkyl (meth)acrylate in which an alkoxyalkyl group has 2 to 30 carbon atoms such as butoxyethyl (meth)acrylate;

aminoalkyl (meth)acrylate in which a (monoalkyl or dialkyl) aminoalkyl group has 1 to 20 carbon atoms in total such as N,N-dimethylaminoethyl (meth)acrylate;

(meth)acrylate of polyalkylene glycol alkyl ether in which an alkylene chain has 1 to 10 carbon atoms and terminal alkyl ether has 1 to 10 carbon atoms such as (meth)acrylate of diethylene glycol ethyl ether, (meth)acrylate of triethylene glycol butyl ether, (meth)acrylate of tetraethylene glycol monomethyl ether, (meth)acrylate of hexaethylene glycol monomethyl ether, monomethyl ether (meth)acrylate of octaethylene glycol, monomethyl ether (meth)acrylate of nonaethylene glycol, monomethyl ether (meth)acrylate of dipropylene glycol, monomethyl ether (meth)acrylate of heptapropylene glycol, and monoethyl ether (meth)acrylate of tetraethylene glycol;

(meth)acrylate of polyalkylene glycol aryl ether in which an alkylene chain has 1 to 30 carbon atoms and terminal aryl ether has 6 to 20 carbon atoms such as (meth)acrylate of hexaethylene glycol phenyl ether;

(meth)acrylate having an alicyclic structure and having 4 to 30 carbon atoms in total such as cyclohexyl (meth)acrylate, dicyclopentanyl (meth)acrylate, isobornyl (meth)acrylate, and methylene oxide-added cyclodecatriene (meth)acrylate;

fluorinated alkyl (meth)acrylate having 4 to 30 carbon atoms in total such as heptadecafluorodecyl (meth)acrylate;

(meth)acrylate having a hydroxyl group such as 2-hydroxyethyl (meth)acrylate, 3-hydroxypropyl (meth)acrylate, 4-hydroxybutyl (meth)acrylate, mono(meth)acrylate of triethylene glycol, tetraethylene glycol mono(meth)acrylate, hexaethylene glycol mono(meth)acrylate, octapropylene glycol mono(meth)acrylate, and mono(meth)acrylate of glycerol;

(meth)acrylate having a glycidyl group such as glycidyl (meth)acrylate; polyethylene glycol mono(meth)acrylate having an alkylene chain having 1 to 30 carbon atoms such as tetraethylene glycol mono(meth)acrylate, hexaethylene glycol mono(meth)acrylate, and octapropylene glycol mono(meth)acrylate; and

(meth)acrylamide such as (meth)acrylamide, N,N-dimethyl (meth)acrylamide, N-isopropyl (meth)acrylamide, 2-hydroxyethyl (meth)acrylamide, and acryloyl morpholine.

Examples of the aromatic monofunctional acrylate monomer include aralkyl (meth)acrylate having an aralkyl group having 7 to 20 carbon atoms such as benzyl (meth)acrylate.

The first polymerizable compound is preferably aliphatic or aromatic alkyl (meth)acrylate in which an alkyl group has 4 to 30 carbon atoms and more preferably n-octyl (meth)acrylate, lauryl (meth)acrylate, stearyl (meth)acrylate, cyclohexyl (meth)acrylate, dicyclopentanyl (meth)acrylate, isobornyl (meth)acrylate, and methylene oxide-added cyclodecatriene (meth)acrylate. This is because dispersibility of quantum dots is improved. As the dispersibility of the quantum dots is improved, the light intensity orthogonal to the exit surface from the light conversion layer increases, and thus the improvement is effective for improving front brightness and front contrast.

Examples of a monofunctional epoxy compound having one epoxy group include phenyl glycidyl ether, p-tert-butylphenyl glycidyl ether, butyl glycidyl ether, 2-ethylhexyl glycidyl ether, allyl glycidyl ether, 1,2-butylene oxide, 1,3-butadiene monoxide, 1,2-epoxydodecane, epichlorohydrin, 1,2-epoxydecane, styrene oxide, cyclohexene oxide, 3-methacryloyloxymethylcyclohexene oxide, 3-acryloyloxymethylcyclohexene oxide, 3-vinylcyclohexene oxide, and 4-vinylcyclohexene oxide.

As an example of the monofunctional oxetane compound having one oxetanyl group, a compound obtained by appropriately substituting an epoxy group of a monofunctional epoxy compound with an oxetane group may be used. As the compound having an oxetane ring, a monofunctional compound out of oxetane compounds disclosed in JP2003-341217A and JP2004-91556A may be apporopriately selected.

The content of the first polymerizable compound is preferably 5 to 99.9 parts by mass and more preferably 20 to 85 parts by mass with respect to the total mass of 100 parts by mass of the first polymerizable compound and the second polymerizable compound. The reason is described below.

<Second Polymerizable Compound>

The second polymerizable compound is a polyfunctional (meth)acrylate monomer and a monomer having two or more functional groups selected from the group consisting of an epoxy group and an oxetanyl group in a molecule.

Among difunctional or higher functional polyfunctional (meth)acrylate monomers, preferable examples of the difunctional (meth)acrylate monomer include neopentyl glycol di(meth)acrylate, 1,6-hexanediol di(meth)acrylate, 1,9-nonanediol di(meth)acrylate, 1,10-decanediol diacrylate, tripropylene glycol di(meth)acrylate, ethylene glycol di(meth)acrylate, tetraethylene glycol di(meth)acrylate, hydroxypivalic acid neopentyl glycol di(meth)acrylate, polyethylene glycol di(meth)acrylate, tricyclodecane dimethanol diacrylate, and ethoxylated bisphenol A diacrylate.

Among the difunctional or higher functional polyfunctional (meth)acrylate monomers, preferable examples of the trifunctional or higher functional (meth)acrylate monomer include epichlorohydrin (ECH)-modified glycerol tri(meth)acrylate, ethylene oxide (EO)-modified glycerol tri(meth)acrylate, propylene oxide (PO)-modified glycerol tri(meth)acrylate, pentaerythritol triacrylate, pentaerythritol tetraacrylate, EO-modified phosphoric acid triacrylate, trimethylolpropane tri(meth)acrylate, caprolactone-modified trimethylolpropane tri(meth)acrylate, EO-modified trimethylolpropane tri(meth)acrylate, PO-modified trimethylolpropane tri(meth)acrylate, tris(acryloxyethyl) isocyanurate, dipentaerythritol hexa(meth)acrylate, dipentaerythritol penta(meth)acrylate, caprolactone-modified dipentaerythritol hexa(meth)acrylate, dipentaerythritol hydroxypenta(meth)acrylate, alkyl-modified dipentaerythritol penta(meth)acrylate, dipentaerythritol poly(meth)acrylate, alkyl-modified dipentaerythritol tri(meth)acrylate, ditrimethylolpropane tetra(meth)acrylate, pentaerythritol ethoxytetra(meth)acrylate, and pentaerythritol tetra(meth)acrylate.

As the polyfunctional monomer, a (meth)acrylate monomer having a urethane bond in the molecule, and specific examples thereof include an adduct of tolylene diisocyanate (TDI) and hydroxyethyl acrylate, an adduct of isophorone diisocyanate (IPDI) and hydroxyethyl acrylate, an adduct of hexamethylene diisocyanate (HDI) and pentaerythritol triacrylate (PETA) a compound manufactured by causing an adduct of TDI and PETA to react with isocyanate and dodecyloxyhydroxypropyl acrylate, and an adduct of 6,6 nylon and TDI, and an adduct of pentaerythritol, TDI, and hydroxyethyl acrylate.

As the monomer having two or more functional groups selected from the group consisting of an epoxy group and an oxetanyl group, for example, an aliphatic cyclic epoxy compound, bisphenol A diglycidyl ether, bisphenol F diglycidyl ether, bisphenol S diglycidyl ether, brominated bisphenol A diglycidyl ether, brominated bisphenol F diglycidyl ether, brominated bisphenol S diglycidyl ether, hydrogenated bisphenol A diglycidyl ether, hydrogenated bisphenol F diglycidyl ether, hydrogenated bisphenol S diglycidyl ether, 1,4-butanediol diglycidyl ether, 1,6-hexanediol diglycidyl ether, glycerin triglycidyl ether, trimethylolpropane triglycidyl ether, polyethylene glycol diglycidyl ether, polypropylene glycol diglycidyl ethers; polyglycidyl ethers of polyether polyols obtained by adding one or more alkylene oxides to aliphatic polyhydric alcohol such as ethylene glycol, propylene glycol, and glycerin; diglycidyl esters of aliphatic long chain dibasic acid; glycidyl esters of higher fatty acid; and a compound including epoxycycloalkane are suitably used.

Examples of the commercially available product that may be suitably used as a monomer having two or more functional groups selected from the group consisting of an epoxy group and an oxetanyl group include CELLOXIDE 2021P and CELLOXIDE 8000 manufactured by Daicel Corporation and 4-vinylcyclohexene dioxide manufactured by Sigma-Aldrich Co. Llc.

A method of manufacturing the monomer having two or more functional groups selected from the group consisting of an epoxy group and an oxetanyl group is not particularly limited, but the synthesis may be performed with reference to Maruzen K.K. Experimental Chemistry Course, 4th Edition, 20, Organic synthesis II, 213˜, 1992, Ed. by Alfred Hasfner, Ed. by Alfred Hasfner,The chemistry of heterocyclic compounds-Small Ring Heterocycles part 3 Oxiranes, John & Wiley and Sons, An Interscience Publication, New York, 1985, Yoshimura, Adhesion, Vol. 29, No. 12, 32, 1985, Yoshimura, Adhesion, Vol. 30, No. 7, 42, 1986, JP1999-100378A (JP-H11-100378A), JP2906245B, and JP2926262B.

The content of the second polymerizable compound is preferably 0.1 to 95 parts by mass and more preferably 15 to 80 parts by mass with respect to the total mass of 100 parts by mass of the first polymerizable compound and the second polymerizable compound. The reason is described below.

The matrix for forming the wavelength conversion layer 26, in other words, the polymerizable composition that becomes the wavelength conversion layer 26, may include necessary components such as a viscosity regulator and a solvent, if necessary. The polymerizable composition that becomes the wavelength conversion layer 26 is, in other words, a polymerizable composition for forming the wavelength conversion layer 26.

<Viscosity Regulator>

The polymerizable composition may include a viscosity regulator, if necessary. The viscosity regulator is preferably a filler having a particle diameter of 5 to 300 nm. The viscosity regulator is preferably a thixotropic agent for providing thixotropy properties. According to the present invention, thixotropy properties refer to properties of reducing the viscosity with increasing the shear rate in a liquid composition, and the thixotropic agent refers to a material that is included in a liquid composition and has a function of providing thixotropy properties to the composition.

Specific examples of the thixotropic agent include fumed silica, alumina, silicon nitride, titanium dioxide, calcium carbonate, zinc oxide, talc, mica, feldspar, kaolinite (kaolin clay), pyrophylite (wax rock clay), sericite (silk mica), bentonite, smectite vermiculite (montmorillonite, beidellite, non-toronite, and saponite), organic bentonite, and organic smectite.

In the polymerizable composition for forming the wavelength conversion layer 26,the viscosity is 3 to 50 mPa·s in a case where a shear rate is 500 s⁻¹ and preferably 100mPa·s or more in a case where a shear rate is 1 s⁻¹. In this manner, in order to adjust the viscosity, it is preferable to use the thixotropic agent.

The reason why that the viscosity of the polymerizable composition is preferably 3 to 50 mPa·s in a case where the shear rate is 500 s⁻¹ and preferably 100 mPa·s or more in a case where a shear rate is 1 s⁻¹ is as follows.

Examples of the method of manufacturing the wavelength conversion sheet 16 (the wavelength conversion layer 26) include a method including a step of preparing two sheets of the supporting films 28, coating a front surface of the supporting film 28 on one side with the polymerizable composition that becomes the wavelength conversion layer 26,bonding the other supporting film 28 to the coated polymerizable composition and curing the polymerizable composition, to form the wavelength conversion layer 26. In the description below, the supporting film 28 that is coated with the polymerizable composition is referred to as a first substrate, and the other supporting film 28 that is attached to the polymerizable composition with which the first substrate is coated is referred to as a second substrate.

In this production method, it is preferable that, in a case where the first substrate is coated with the polymerizable composition, the polymerizable composition is uniformly applied not to form coating streaks such that the film thickness of the coating film is uniform. For this reason, in view of coatability and levelability, it is preferable that the viscosity of the polymerizable composition is low. Meanwhile, in order to bond the second substrate on the polymerizable composition applied to the first substrate, in order to uniformly the second substrate, it is preferable that it is preferable that the resistance to pressure during bonding is high, and in this point of view, it is preferable that the viscosity of the polymerizable composition is high.

The shear rate of 500 s⁻¹ is a representative value of a representative value applied to the polymerizable composition applied to the first substrate, and the shear rate of 1 s⁻¹ is a representative value of a shear rate applied to the polymerizable composition immediately before the bonding of the second substrate to the polymerizable composition. The shear rate 1 s⁻¹ is merely a representative value. In a case where the second substrate is bonded to the polymerizable composition applied to the first substrate, if the first substrate and the second substrate are transported at the same rate and bonded to each other, the shear rate applied to the polymerizable composition is almost 0 s⁻¹, and the shear rate applied to the polymerizable composition in the actual manufacturing process is not limited to 1 s⁻¹. Meanwhile, the shear rate of 500 s⁻¹ is merely a representative value in the same manner, and the shear rate applied to the polymerizable composition in the actual manufacturing process is not limited to 500 s⁻¹.

In view of uniformly coating and bonding, the viscosity of the polymerizable composition is 3 to 50 mPa·s, in a case where the representative value of the shear rate applied to the polymerizable composition in a case of coating the first substrate with the polymerizable composition is 500 s⁻¹, and it is preferable that the viscosity thereof is adjusted to be 100 mPa·s or more in a case where the representative value of the shear rate applied to the polymerizable composition immediately before the second substrate is bonded to the polymerizable composition applied to the first substrate is 1 s⁻¹.

<Solvent>

The polymerizable composition that becomes the wavelength conversion layer 26 may include a solvent, if necessary. The type and the addition amount of the solvent used in this case is not particularly limited. For example, as the solvent, the organic solvent may be used singly or two or more kinds thereof may be used in a mixture.

The polymerizable composition that becomes the wavelength conversion layer 26 may include a compound having a fluorine atom such as trifluoroethyl (meth)acrylate, pentafluoroethyl (meth)acrylate, (perfluorobutyl) ethyl (meth)acrylate, perfluorobutyl-hydroxypropyl (meth)acrylate, (perfluorohexyl) ethyl (meth)acrylate, octafluoropentyl (meth)acrylate, perfluorooctylethyl (meth)acrylate, and tetrafluoropropyl (meth)acrylate.

The coatability may be improved by including these compounds.

<Hindered Amine Compound>

The polymerizable composition that becomes the wavelength conversion layer 26 may include a hindered amine compound, if necessary.

Examples of the hindered amine compound include 2,2,6,6-tetramethyl-4-piperidyl benzoate, N-(2,2,6,6-tetramethyl-4-piperidyl) dodecylsuccinimide, 1-[(3,5-di-tert-butyl-4-hydroxyphenyl) propionyloxyethyl]-2,2,6,6-tetramethyl-4-piperidyl-(3,5-di-tert-butyl-4-hydroxyphenyl) propionate, bis(2,2,6,6-tetramethyl-4-piperidyl) sebacate, bis(1,2,2,6,6-pentamethyl-4-piperidyl) sebacate, bis(1,2,2,6,6-pentamethyl-4-piperidyl)-2-butyl-2-(3,5-di-tert-butyl-4-hydroxybenzyl) malonate, N,N′-bis(2,2,6,6-tetramethyl-4-piperidyl) hexamethylenediamine, tetra(2,2,6,6-tetramethyl-4-piperidyl) butane tetracarboxylate, tetra(1,2,2,6,6-pentamethyl-4-piperidyl) butane tetracarboxylate, bis(2,2,6,6-tetramethyl-4-piperidyl).di(tridecyl) butane tetracarboxylate, bis(1,2,2,6,6-pentamethyl-4-piperidyl).di(tridecyl) butane tetracarboxylate, 3,9-bis[1,1-dimethyl-2-{tris(2,2,6,6-tetramethyl-4-piperidyloxycarbonyloxy) butylcarbonyloxy} ethyl]-2,4,8,10-tetraoxaspiro [5.5] undecane, 3,9-bis[1,1-dimethyl-2-tris(1,2,2,6,6-pentamethyl-4-piperidyloxycarbonyloxy) butylcarbonyloxy} ethyl]-2,4,8,10-tetraoxaspiro [5.5] undecane, 1,5,8,12-tetrakis[4,6-bis{N-(2,2,6,6-tetramethyl-4-piperidyl) butylamino}-1,3,5-triazin-2-yl]-1,5,8,12-tetraazadodecane, a 1-(2-hydroxyethyl)-2,2,6,6-tetramethyl-4-piperidinol/dimethyl succinate condensate, a 2-tert-octylamino-4,6-dichloro-s-triazine/N,N′-bis(2,2,6,6-tetramethyl-4-piperidyl) hexamethylenediamine condensate, an N,N′-bis(2,2,6,6-tetramethyl-4-piperidyl) hexamethylenediamine/dibromoethane condensate, bis(1-undecanoxy-2,2,6,6-tetramethylpiperidin-4-yl) carbonate, 1,2,2,6,6-pentamethyl-4-piperidyl methacrylate, and 2,2,6,6-tetramethyl-4-piperidyl methacrylate.

In a case where the hindered amine compound is added, it is preferable to restraint the coloration of the wavelength conversion layer 26 to light having high illuminance

In the wavelength conversion layer 26, an amount of the resin that becomes a matrix may be appropriately determined according to the kinds of the functional materials included in the wavelength conversion layer 26.

In the illustrated example, since the wavelength conversion layer 26 is a quantum dot layer, the content of the resin that becomes a matrix is preferably 90 to 99.9 parts by mass and more preferably 92 to 99 parts by mass with respect to the total mass of 100 parts by mass of the quantum dot layer.

The thickness of the wavelength conversion layer 26 may be also appropriately determined according to the types of the wavelength conversion layer 26 or the application of the wavelength conversion sheet 16.

In the illustrated example, since the wavelength conversion layer 26 is a quantum dot layer, and thus in view of handling properties and light emission characteristics, the thickness of the wavelength conversion layer 26 is preferably 5 to 200 μm and more preferably 10 to 150 μm.

The thickness of the wavelength conversion layer 26 intends an average thickness, and the average thickness is obtained by measuring thicknesses of the quantum dot layer at 10 or more optional points and arithmetically averaging the thicknesses.

In the polymerizable composition that becomes the wavelength conversion layer 26 such as a quantum dot layer, a polymerization initiator, a silane coupling agent, or the like may be added, if necessary.

As the supporting film 28, various film-like materials (sheet-like materials) that are capable of supporting the polymerizable compositions that become the wavelength conversion layer 26 and the wavelength conversion layer 26 may be used.

The supporting film 28 is preferably a so-called gas barrier film obtained by forming a gas barrier layer through which oxygen or the like does not pass on the front surface of the supporting substrate. That is, it is preferable that the supporting film 28 covers the main surface of the wavelength conversion layer 26 and also functions as a member for suppressing the infiltration of moisture or oxygen from a main surface of the wavelength conversion layer 26.

It is preferable that, with respect to the wavelength conversion sheet 16, the supporting films 28 on both main surfaces of the wavelength conversion layer 26 are gas barrier films, but according to the present invention, the present invention is not limited thereto. For example, in a case where it is less likely to infiltrate moisture or oxygen from the main surface on one side of the wavelength conversion sheet 16, a configuration in which the supporting film 28 only on one main surface of the wavelength conversion layer 26 is a gas barrier film may be provided. However, in order to more reliably prevent the deterioration of the wavelength conversion layer 26 due to moisture or oxygen, it is preferable that the supporting films 28 on both of the main surfaces of the wavelength conversion layer 26 are gas barrier films, as in the illustrated example.

As described above, it is preferable that the supporting film 28 is a gas barrier film. Specifically, the water vapor permeability of the supporting film 28 is preferably 1×10⁻³ g/(m² day) or less. The oxygen permeability of the supporting film 28 is preferably 1×10⁻² cc/(m²day·atm) or less.

In a case where the supporting film 28 having the low water vapor permeability and the low oxygen permeability, that is, having high gas barrier properties is used, it is possible to prevent the infiltration of moisture or oxygen to the wavelength conversion layer 26 and suitably prevent the deterioration of the wavelength conversion layer 26.

For example, the water vapor permeability is measured by the MOCON method under conditions of the temperature of 40° C. and a relative humidity of 90% RH. In a case where the water vapor permeability is greater than the measurement limit of the MOCON method, the water vapor permeability is measured by the calcium corrosion method (method disclosed in JP2005-283561A under the same conditions. For example, the oxygen permeability may be measured under the conditions of the temperature of 25° C. and the humidity of 60% RH by using a determination device (manufactured by Nippon API Co., Ltd.), according to the APIMS method (atmospheric pressure ionization mass spectrometry).

The thickness of the supporting film 28 is preferably 5 to 100 μm, more preferably 10 to 70 μm, and particularly preferably 15 to 55 μm.

It is preferable that the thickness of the supporting film 28 is 5 μm or more, since the thickness of the wavelength conversion layer 26 may be caused to be uniform in a case of forming the wavelength conversion layer 26 between two supporting films 28. It is preferable that the thickness of the supporting film 28 is caused to be 100 μm or less, since the entire thickness of the wavelength conversion sheet 16 including the wavelength conversion layer 26 may be caused to be thin.

As described above, as the supporting film 28, various kinds of films that are capable of supporting the wavelength conversion layer 26 or the polymerizable composition may be used, and various kinds of films having desired gas barrier properties is preferably used.

Here, the supporting film 28 is preferably transparent, and, for example, glass, a transparent inorganic crystalline material, a transparent resin material, or the like may be used. The supporting film 28 may have a rigid sheet shape or may have a flexible film shape. The supporting film 28 may have an elongate shape capable of being wound or may have a sheet-like shape that may be cut into predetermined dimensions in advance.

In a case where a gas barrier film is used as the supporting film 28, various kinds of gas barrier films may be used. For example, an organic-inorganic lamination type gas barrier film obtained by forming one or more sets of the combination of a supporting substrate, an inorganic layer as a gas barrier layer on a supporting substrate, and an organic layer that becomes a base substrate (formation surface) of the inorganic layer may be suitably used.

Examples thereof include a gas barrier film having one set of the combination of an inorganic layer and a base substrate organic layer, which has an organic layer on one front surface of the supporting substrate and has an inorganic layer on the front surface of the organic layer using an organic layer as a base substrate layer.

Examples thereof include a gas barrier film having two sets of the combination of inorganic layers and a base substrate organic layers, which has an organic layer on one front surface of the supporting substrate, has an inorganic layer on the front surface of the organic layer using the organic layer as a base substrate layer, has a second organic layer on the inorganic layer, and has a second inorganic layer using the second organic layer as a base substrate layer.

Otherwise, a gas barrier film having three or more sets of inorganic layers and base substrate organic layers may be used. Basically, as more sets of the combination of inorganic layers and base substrate organic layers are provided, higher gas barrier properties may be obtained.

In the organic-inorganic lamination type gas barrier film, gas barrier properties are mainly exhibited in the inorganic layers. In the following descriptions, the “organic-inorganic lamination type gas barrier film” is also referred to as a “lamination type gas barrier film”.

Accordingly, in order to use a lamination type gas barrier film as the supporting film 28 of the wavelength conversion sheet 16, in all layer configurations, it is preferable that an upper most layer, that is, an outermost layer on an opposite side of the supporting substrate, is an inorganic layer, and an inorganic layer is provided on the inner side, that is, on the wavelength conversion layer 26 side. That is, in a case where the lamination type gas barrier film is used as the supporting film 28 of the wavelength conversion sheet 16, it is preferable that, as a state in which the inorganic layer comes into contact with the wavelength conversion layer 26,the wavelength conversion layer 26 is sandwiched between the supporting films 28. Accordingly, it is possible to suitably prevent infiltration of oxygen or the like from the end face of the organic layer to the wavelength conversion layer 26.

As the supporting substrate of the lamination type gas barrier film, various kinds of supports used as supports in well-known gas barrier films may be used.

Among these, in view of easiness of thinning, lightweight and suitability for flexibility, or the like, a film including various kinds of plastics (polymer materials/resin materials) are suitably used.

Specifically, suitable examples thereof include resin films including polyethylene (PE), polyethylene naphthalate (PEN), polyamide (PA), polyethylene terephthalate (PET), polyvinyl chloride (PVC), polyvinyl alcohol (PVA), polyacritonitrile (PAN), polyimide (PI), transparent polyimide, polymethylmethacrylate resin (PMMA), polycarbonate (PC), polyacrylate, polymethacrylate, polypropylene (PP), polystyrene (PS), ABS, a cycloolefin copolymer (COC), a cycloolefin polymer (COP), and triacetylcellulose (TAC).

In a case where a gas barrier film may be used in the supporting film 28, these resin films may be suitably used as the supporting film 28.

The thickness of the supporting substrate may be appropriately set according to the application or the size thereof. According to the research by the present inventors, the thickness of the supporting substrate is preferably about 10 to 100 μm. In a case of where the thickness of the supporting substrate is caused to be in this range, preferable results in view of lightweight or thinning may be obtained.

With respect to the supporting substrate, functions such as anti-reflection, the phase difference control, the light extraction efficiency improvement, and the like may be provided on the front surface of such a plastic film.

As described above, in the lamination type gas barrier film, the gas barrier layer mainly has an inorganic layer exhibiting gas barrier properties and a organic layer that becomes a base substrate layer of the inorganic layer.

In the lamination type gas barrier film, it is preferable that the upper most layer is an inorganic layer, and the inorganic layer side faces the wavelength conversion layer 26. However, the lamination type gas barrier film may have an organic layer for protecting the inorganic layer on the upper most layer, if necessary. However, the lamination type gas barrier film may have an organic layer for securing the adhesiveness to the wavelength conversion layer 26 on the upper most layer, if necessary. The organic layer for securing the adhesiveness may function as a protective layer of the inorganic layer.

The organic layer becomes a base substrate layer of an inorganic layer that mainly exhibits gas barrier properties in the lamination type gas barrier film.

As the organic layer, various kinds of layers used as the organic layer in the well-known lamination type gas barrier film may be used. For example, as the organic layer, a film which is obtained by using an organic compound as a main component and which is basically formed by crosslinking a monomer and/or an oligomer may be used.

The lamination type gas barrier film has an organic layer that becomes a base substrate of an inorganic layer, such that the unevenness of the front surface of the supporting substrate or foreign matters and the like adhering to the front surface may be embedded so as to form an adequate deposition surface of the inorganic layer. As a result, an adequate inorganic layer without fractures or cracks may be formed on the entire deposition surface. High gas barrier properties in which the water vapor permeability is 1×10⁻³ g/(m² day) or less, and the oxygen permeability is 1×10⁻² cc/(m² day atm) or less may be obtained.

In a case where the lamination type gas barrier film has an organic layer that becomes this base substrate, this organic layer functions as the cushion of the inorganic layer. Therefore, in a case where the inorganic layer is impacted from the outside or the like, the damage of the inorganic layer may be prevented by the cushioning effect of the organic layer.

In the lamination type gas barrier film, the inorganic layer adequately exhibits gas barrier properties, and deterioration of the wavelength conversion layer 26 due to moisture or oxygen may be suitably prevented.

In the lamination type gas barrier film, as the material for forming the organic layer, various kinds of organic compounds (resins/polymer compounds) may be used.

Particularly, appropriate examples thereof include films of a thermoplastic resin such as polyester, acrylic resin, methacrylic resin, a methacrylic acid-maleic acid copolymer, polystyrene, transparent fluororesin, polyimide, fluorinated polyimide, polyamide, polyamide imide, polyether imide, cellulose acylate, polyurethane, polyether ether ketone, polycarbonate, alicyclic polyolefin, polyarylate, polyethersulfone, polysulfone, fluorene ring modified polycarbonate, alicyclic modified polycarbonate, fluorene ring modified polyester, an acryloyl compound, polysiloxane, or other organosilicon compounds. The plurality of these may be used in combination.

Among these, in view of excellent glass transition temperature and excellent strength, an organic layer including a polymer of a cationically polymerizable compound having a radically polymerizable compound and/or an ether group as a functional group is suitable.

Among these, particularly, in addition to the strength, in view of a low refractive index, high transparency, and excellent optical properties, an acrylic resin and a methacrylic resin that has a polymer of a monomer or an oligomer of acrylate and/or methacrylate as a main component and that has a glass transition temperature of 120° C. or more are suitably exemplified as an organic layer. Among these, particularly, acrylic resins and methacrylic resins that have polymers of difunctional or higher functional, particularly, trifunctional or higher functional monomers or oligomers of acrylate and/or methacrylate such as dipropylene glycol di(meth)acrylate (DPGDA), trimethylolpropane tri(meth)acrylate (TMPTA), and dipentaerythritol hexa(meth)acrylate (DPHA), as main components are suitably exemplified. A plurality of these acrylic resins and methacrylic resins may be preferably used.

In a case where the organic layer is formed with such an acrylic resin or methacrylic resin, an inorganic layer may be formed on a base substrate with a firm skeleton, and thus a denser inorganic layer having high gas barrier properties may be formed.

The thickness of the organic layer is preferably 1 to 5 μm.

In a case where the thickness of the organic layer is 1 μm or more, an adequate deposition surface of the inorganic layer may be more suitably obtained, and thus an adequate inorganic layer without fractures, cracks, or the like may be formed on the entire deposition surface.

In a case where the thickness of the organic layer is caused to be 5 μm or less, it is possible to suitably prevent the problems occurring due to a too thick organic layer such as cracks of the organic layer or curling of a lamination type gas barrier film.

In view of the above, it is more preferable that the thickness of the organic layer is 1 to 3 μm.

In a case where the lamination type gas barrier film has a plurality of organic layers as base substrate layers, the thicknesses of the organic layers may be identical to or different from each other.

In a case where the lamination type gas barrier film has a plurality of organic layers, materials for forming the respective organic layers may be identical to or different from each other. However, in view of productivity, it is preferable that all of the organic layers are formed with the same materials.

It is preferable that the organic layer is formed by the well-known method such as a coating method or a flash vapor deposition method.

In order to improve adhesiveness to an inorganic layer that becomes an underlayer of an organic layer, it is preferable that the organic layer contains a silane coupling agent.

An inorganic layer using this organic layer as a base substrate is formed on the organic layer. The inorganic layer is a film using an inorganic compound as a main component and mainly exhibits gas barrier properties in the lamination type gas barrier film.

As the inorganic layer, various kinds of films that exhibit gas barrier properties and that includes metal oxide, metal nitride, metal carbide, metal carbonitride may be used.

Specifically, a film formed of an inorganic compound, for example, metal oxide such as aluminum oxide, magnesium oxide, tantalum oxide, zirconium oxide, titanium oxide, and indium tin oxide (ITO), metal nitride such as aluminum nitride; metal carbide such as aluminum carbide; silicon oxide such as silicon oxide, silicon oxynitride, silicon oxycarbide, and silicon oxynitride carbide; silicon nitride such as silicon nitride, and silicon nitride carbide; silicon carbide such as silicon carbide; hydride thereof; a mixture of two or more of these; and a hydrogen-containing matter of these is suitably exemplified. According to the present invention, silicon is also considered as metal.

Particularly, in view of exhibiting high transparency and excellent gas barrier properties, a film including a silicon compound such as silicon oxide, silicon nitride, and silicon oxynitride is suitably exemplified. Among these, particularly, a film including silicon nitride has high transparency, in addition to excellent gas barrier properties and is suitably exemplified.

In a case where the lamination type gas barrier film has a plurality of inorganic layers, materials for forming the inorganic layers may be identical to or different from each other. However, considering the productivity, it is preferable that all of the inorganic layers are formed of the same material.

With respect to the thickness of the inorganic layer, the thickness capable of exhibiting desired gas barrier properties may be appropriately determined according to the forming material. According to the research by the present inventors, the thickness of the inorganic layer is preferably 10 to 200 nm.

In a case where the thickness of the inorganic layer is 10 nm or more, it is possible to form an inorganic layer that stably exhibits sufficient gas barrier properties. The inorganic layer is generally brittle, and in a case where the inorganic layer is too thick, it is likely that fractures, cracks, peeling and the like may occur. However, in a case where the thickness of the inorganic layer is caused to be 200 nm or less, occurrence of the fractures may be prevented.

Considering the above, the thickness of the inorganic layer is preferably 10 to 100 nm and more preferably 15 to 75 nm.

In a case where the lamination type gas barrier film has a plurality of inorganic layers, the thicknesses of the respective inorganic layers may be identical to or different from each other.

The inorganic layer may be formed by the well-known method according to the forming material. Specifically, plasma CVD such as capacitively coupled plasma (CCP)-chemical vapor deposition (CVD) or inductively coupled plasma (ICP)-CVD, sputtering such as magnetron sputtering or reactive sputtering, and a vapor phase deposition method such as vapor deposition are suitably exemplified.

In the wavelength conversion sheet 16, it is preferable that an end face is covered with an end face sealing layer including a material exhibiting gas barrier properties. Accordingly, it is possible to prevent infiltration of oxygen from an end face of the wavelength conversion sheet 16 to the wavelength conversion layer 26.

As the end face sealing layer, various kinds of layers including a material having gas barrier properties for inhibiting passing of oxygen or moisture, such as a metal layer such as a plating layer, an inorganic compound layer such as a silicon oxide layer and/or a silicon nitride layer, and a resin layer including a resin material such as an epoxy resin or a polyvinyl alcohol resin may be used. The end face sealing layer may have a multilayer configuration such as a configuration of including a base substrate metal layer and a plating layer or a configuration including a polyvinyl alcohol layer as an underlayer (the wavelength conversion sheet 16 side) and an epoxy resin layer as an upper layer.

In the lighting device 10, the (point) light source 18 is arranged at the center position of the bottom surface inside the housing 14. The light source 18 is a light source of light applied by the lighting device 10.

As the light source 18, various kinds of well-known point light sources may be used, as long as the point light sources apply light having a wavelength that may be converted by the wavelength conversion sheet 16 (the wavelength conversion layer 26).

Among these, a light emitting diode (LED) is suitably exemplified as the light source 18. As described above, as the wavelength conversion layer 26 of the wavelength conversion sheet 16, a quantum dot layer obtained by dispersing a quantum dot in a matrix of a resin or the like is suitably used. Therefore, as the light source 18, a blue light emitting diode (blue LED) that applies blue light is particularly and suitably used. Among these, particularly, a blue LED having a peak wavelength of 450 nm±50 nm is suitably used.

In the lighting device 10 of the present invention, the output of the light source 18 is not particularly limited and may be appropriately set according to the illuminance (brightness) of light and the like required in the lighting device 10.

The light emitting performances of the light source 18 such as a peak wavelength, a profile of illuminance, and a full width at half maximum are not particularly limited and may be appropriately set according to the size of the lighting device 10, the distance between the light source 18 and the wavelength conversion sheet 16, performances of the wavelength conversion layer 26, and the gap of the light sources 18 in a case of arranging the plurality of light sources 18.

Here, in the lighting device 10 of the present invention, it is preferable that the light applied by the light source 18 has high directivity. Specifically, in the light source 18, a full width at half maximum (luminance half-value angle) is preferably 70° or less and more preferably 65° or less.

It is preferable that local dimming (local luminance control) is performed in a case of using the plurality of light sources 18 that may increase the illuminance of the light applied by the wavelength conversion sheet 16 by causing the full width at half maximum of the light source 18 to be 70° or less, since the influence of the light source 18 is reduced, and the contrast in the screen may be caused to be clear.

In the lighting device 10, the light intensity reduction member 20 is provided on the surface (inner surface) on the housing 14 side of the wavelength conversion sheet 16, that is, on the light incident surface of the wavelength conversion sheet 16.

In the following description, the “light incident surface of the wavelength conversion sheet 16” is simply referred to as the “light incident surface”.

In the illustrated example, the light intensity reduction member 20 is a sheet-like material that is attached to the light incident surface and is also referred to as a light intensity reduction layer.

The light intensity reduction member 20 (light intensity reduction member) reduces the peak illuminance of light applied by the light source 18 on the light incident surface by 10% to 80%.

That is, as conceptually illustrated on the left side of FIG. 3, in a case where the light intensity reduction member 20 is not provided, the peak illuminance of the light applied from the light source 18 on the light incident surface is caused to be 100%. In a case where the light intensity reduction member 20 reflects and/or absorbs light applied by the light source 18, the peak illuminance on the light incident surface of light applied by the light source 18 is reduced by 10% to 80% from a case where the light intensity reduction member 20 (100%) is not provided as conceptually illustrated on the right side of FIG. 3.

In other words, the light intensity reduction member 20 reflects and/or absorbs light applied by the light source 18, such that the peak illuminance on the light incident surface of light applied by the light source 18 is 20% to 90% in a state in which the light intensity reduction member 20 (100%) is not provided as conceptually illustrated in FIG. 3.

In FIG. 3, the “position” in the lateral axis is a position in the plane direction on the light incident surface of the wavelength conversion sheet 16. The “plane direction” in the present invention is a plane direction of the light incident surface of the wavelength conversion sheet 16.

The lighting device 10 of the present invention has the light intensity reduction member 20, such that the deterioration of the wavelength conversion layer 26 due to light incident to the wavelength conversion sheet 16, heat by the incident light, and heat by the light source 18 is prevented, so as to realize the lighting device 10 having high durability and a long lifespan.

As described above, in the backlight device of the LCD or the like, in order to increase the light utilization efficiency and improve the color reproducibility, the use of a wavelength conversion member that converts a wavelength of incidence rays by a quantum dot is known. Recently, demand for minimizing a display device such as an LCD increases. In the backlight device using the wavelength conversion member, a distance between the light source and the wavelength conversion member becomes short.

However, the wavelength conversion member is easily damaged by light or heat in many cases, and thus the wavelength conversion member deteriorates due to heat and light from a light source with elapse of time.

In a case where a quantum dot is used in the wavelength conversion member, a blue LED is used as a light source, in many cases. Here, the LED has high directivity of light, high peak illuminance, and a high calorific value. As described above, it is preferable that the light source that applies light to the wavelength conversion layer has high directivity.

Therefore, particularly, at the position of the peak illuminance on the incident surface of the wavelength conversion member to which light having high illuminance is incident, the deterioration of the wavelength conversion member due to incident light, heat by incident light, and heat from the light source is severe.

As a result, in the lighting device used in a backlight in the related art, with elapse of time, light having intended light intensity may not be applied to the entire surface in the plane direction.

In contrast, in the lighting device 10 of the present invention, the light intensity reduction member 20 that reflects and/or absorbs light applied by the light source 18 so as to reduce the peak illuminance on the light incident surface of the wavelength conversion sheet 16 by 10% to 80% is provided between the light source 18 and the wavelength conversion sheet 16.

According to the present invention having the configuration, light having excessively high illuminance, such as light having the peak illuminance applied by the light source 18, does not incident to the wavelength conversion layer 26 of the wavelength conversion sheet 16. Therefore, the deterioration of the wavelength conversion layer 26 due to the light applied by the light source 18, the heat of the incident light, and the heat of the light source 18 may be prevented.

In a case where the reduction rate of the illuminance on the light incident surface of the light applied by the light source 18 is less than 10% due to the light intensity reduction member 20, the illuminance reduction effect of the light on the light incident surface may not be sufficiently obtained. As a result, it is not possible to prevent excessive light from being incident to the wavelength conversion layer 26 to deteriorate the wavelength conversion layer 26 due to the light, the heat of light, and the heat of the light source 18.

In contrast, in a case where the reduction rate of the illuminance on the light incident surface of the light applied by the light source 18 caused by the light intensity reduction member 20 is greater than 80%, the illuminance (brightness) of the light applied by the lighting device 10 decreases. As a result, for example, in a case where the lighting device of the present invention is used in the backlight device of the LCD, sufficient backlight brightness may not be obtained.

Considering the above points, the reduction rate of the peak illuminance on the light incident surface of the light applied by the light source 18 caused by the light intensity reduction member 20 is preferably 15% to 70% and more preferably 20% to 60%.

According to the present invention, the reduction rate of the peak illuminance on the light incident surface caused by the light intensity reduction member 20 is measured as below with reference to “JIS C 8152: Method of measuring white light emitting diode (LED) for lighting”.

First, a distance L between the light source 18 and the light incident surface of the wavelength conversion sheet 16 in the lighting device 10 is measured.

The light source 18 is placed on the base 30, and a virtual light incident surface S (see FIG. 5) is set according to the measured distance L and the positional relationship between the light source 18 and the light incident surface in the lighting device 10 in the plane direction. The base 30 is a surface which is the same as the installation surface of the light source 18 in the housing 14 or a surface having the same light reflectivity as the installation surface of the light source 18 in the housing 14.

Generally, the installation surface (the bottom surface of the housing 14) of the light source 18 of the lighting device 10 and the light incident surface are parallel to each other. Accordingly, as the virtual light incident surface S, a surface parallel to the base 30 may be set according to the positional relationship between the light source 18 and the light incident surface in the plane direction and the shape and the size of the light incident surface at the position in the measured distance L from the light source 18 to the light incident surface.

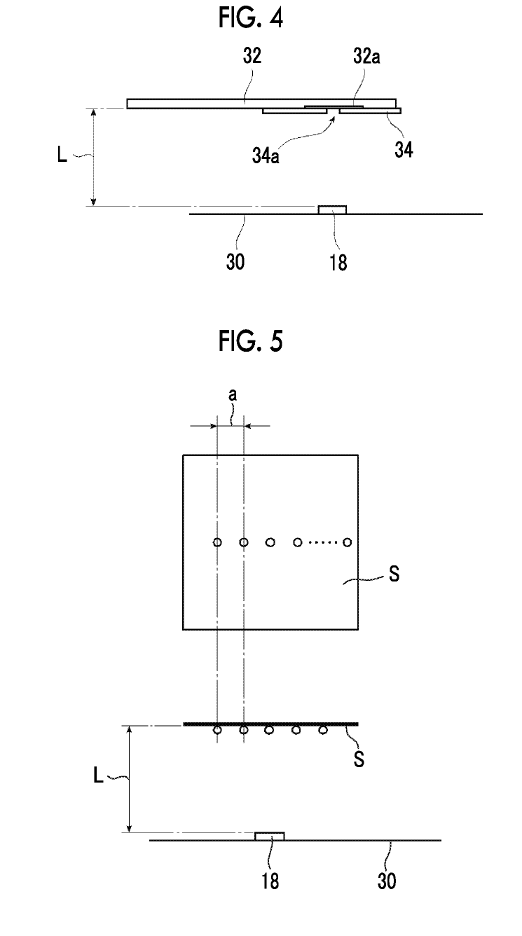

Subsequently, as conceptually illustrated in FIG. 4, the illuminance meter 32 is arranged such that a distance from the light source 18 to a sensor 32a becomes the distance L from the light source 18 to light incident surface, the illuminance on the set virtual light incident surface S is measured by the illuminance meter 32. In the sensor 32a of the illuminance meter 32, a light screen 34 having a rectangular through-hole 34a of 1×1 mm is provided such that the center of the sensor 32a and the center of the through-hole 34a coincide with each other, and light in an region other than the through-hole 34a is shielded.

Examples of the illuminance meter 32 include VEGA manufactured by Ophir Optronics Solutions Ltd.

The illuminance is two-dimensionally measured such that the intersection of the optical axis of the light source 18 and the virtual light incident surface S is included, and an interval aof measurement points (white circles) on the virtual light incident surface S is set to 1 mm as conceptually illustrated in FIG. 5, the maximum value of the illuminance is set as the peak illuminance I₀ₘₐₓ on the light incident surface of the light applied by the light source 18 in a case where the light intensity reduction member 20 is not provided.

Subsequently, according to the positional relationship between the light incident surface and the light intensity reduction member 20 in the lighting device 10, the light intensity reduction member 20 is arranged at the same position as the lighting device 10 with respect to the virtual light incident surface S.

In the same manner as the measurement of the peak illuminance I₀ₘₐₓ, the measurement of the illuminance is performed, and the maximum value of the illuminance is set as peak illuminance I₁ₘₐₓ on the light incident surface of the light applied by the light source 18 in a case where the light intensity reduction member 20 is arranged.

As in the lighting device 10 illustrated in FIG. 1, in a case where the light intensity reduction member 20 is in contact with the light incident surface, the light intensity reduction member 20 is attached to a transparent film such as a PET film, the surface of the unattached front surface of the light intensity reduction member 20 of this film is arranged to coincide with the virtual light incident surface S, the illuminance on this unattached surface is measured with the illuminance meter 32, and the peak illuminance I₁ₘₐₓ is measured.

At this point, the measurement of the peak illuminance I₀ₘₐₓ in a case where the light intensity reduction member 20 is not provided is performed by arranging the front surface of one surface of the same film to which the light intensity reduction member 20 is not attached to coincide with the virtual light incident surface S and measuring the illuminance on the surface coincide with the virtual light incident surface S by the illuminance meter 32.

In the following equation, the reduction rate [%] of the peak illuminance by the light intensity reduction member 20 is calculated by using the measured peak illuminance I₀ₘₐₓ in a case where the light intensity reduction member 20 is not provided and the peak illuminance I₁ₘₐₓ in a case where the light intensity reduction member 20 is not arranged.

Reduction rate [%] of peak illuminance=[1−(I₁ₘₐₓ/I₀ₘₐₓ)]×100

In a case where the light intensity reduction member 20 may reduce the peak illuminance on the light incident surface of the light applied by the light source 18 by 10% to 80% compared with a case where the light intensity reduction member 20 is not provided, the light reflectance, the light transmittance, the forming material, the arrangement position in the plane direction, the arrangement position in the spacing direction between the light source 18 and the wavelength conversion sheet 16, the area, the thickness, the configuration, the shape, and the like are not limited, but it is preferable that the shapes, the configurations, and the like are adjusted according to the intensity profile of the point light source. According to this configuration, the light intensity by the point light source is effectively reduced, and both of the lifespan and the brightness of the irradiated light are easily obtained. Examples thereof include design in which the light reflectance at positions immediately above the point light source or near the optical axis of the point light source is increased, and the light reflectance at the edge part portion is decreased.

The spacing direction between the light source 18 and the wavelength conversion sheet 16 generally coincide with the direction of the optical axis of the light source 18. In other words, the area of the light intensity reduction member 20 is the size of the light intensity reduction member 20 in the plane direction.

That is, according to the present invention, the light intensity reduction member 20 may reduce the peak illuminance on the light incident surface of the light applied by the light source 18 by 10% to 80% compared with the case where the light intensity reduction member 20 is not provided, and in a case where the absorbance of the light having a wavelength of 450 nm measured by using the following integrating sphere is less than 5%, there is no further limitation.

Therefore, the action of light reflection and absorption by the light intensity reduction member 20 is not limited. For example, the light intensity reduction member 20 reflects and/or absorbs incident light by one or more optical actions of the light reflection such as the diffusion reflection, the interference reflection, the specular reflection, the total surface reflection, absorption, or the like, and reduces the peak illuminance of the light incident to the light incident surface. The action of the light reflection in the light intensity reduction member 20 is not limited thereto.

Specific examples of the light intensity reduction member 20 having a diffusion reflection action include a diffusion layer formed by diffusing diffusion particles in a binder. Examples of the light intensity reduction member 20 having an interference reflection action include a laminate of layers having different refractive indices. Examples of the light intensity reduction member 20 having a specular reflection action include a metal film. Examples of the light intensity reduction member 20 having a total surface reflection action include a structure having a prism structure.

Among these, in view of easiness of adjustment of the light intensity reduction effect and easiness of formation, the light intensity reduction member 20 that performs diffusion reflection or total surface reflection is suitably used.

As a material forming the light intensity reduction member 20 that performs diffusion reflection or total surface reflection, materials having low light absorption in the visible light region, excellent light resistance, excellent heat resistance, and excellent moisture resistance are preferable. Examples thereof include a sol-gel material, an epoxy resin, a silicone resin, an acrylic resin, a polyolefin resin, a polyester resin, a polyamide resin, a polyimide resin, a polystyrene resin, and a cellulose derivative resin. These materials may be used singly or a plurality of materials may be compatibilized or one of materials may be dispersed in the other, to be used. With respect to the resin, a resin obtained by polymerizing by light or heat may be used.

As the material for forming the light intensity reduction member 20 that performs diffusion reflection, the composition obtained by dispersing having particles different refractive indexes in a material such as the resin is suitably exemplified. As the particle, particles including the materials and particles including metal oxide such as alumina, silica, titania, zirconia, and zinc oxide, or other metal compounds such as barium sulfate are suitably exemplified. The plurality of particles may be used together. In order to increase the dispersibility of the particles, the particle front surface may be modified.

As the material including the light intensity reduction member 20 that performs diffusion reflection or total surface reflection, more specifically, polydimethylsiloxane, modified polydimethylsiloxane, ethylene glycol (meth)acrylate, urethane (meth)acrylate, alkyl (meth)acrylate, polymethyl (meth)acrylate, polybutyl methacrylate, polyethylene, polypropylene, a cycloolefin polymer, a cycloolefin copolymer, polyester urethane, diacetyl cellulose, and triacetylcellulose are exemplified.

Among these, in view of the light fastness and the heat resistance, polydimethylsiloxane, polymethyl (meth)acrylate, urethane (meth)acrylate, and polyester urethane are particularly preferable.

In view of preventing unevenness and popping after coating, the composition that is a material for forming the light intensity reduction member 20 is preferably a low solid content and high viscosity.

As the composition, compositions using a resin in a high molecular weight are suitable. The composition preferably contains the resin, as the resin in a high molecular weight. As the resin in a high molecular weight, specifically, a resin having a weight-average molecular weight of 40,000 to 10,000,000 g/mol is preferable, a resin having a weight-average molecular weight of 100,000 to 5,000,000g/mol is more preferable, and a resin having a weight-average molecular weight of 500,000 to 3,000,000 g/mol is particularly preferable. In a case where the weight-average molecular weight is low, a sufficient thickening effect on the solid content may not be obtained in some cases. Otherwise, it is not preferable that the weight-average molecular weight is high, since the coating failure such as stringing easily occurs.

In a case where the member that performs total reflection on the light as the light intensity reduction member 20, illuminance (brightness) of the light incident to the wavelength conversion sheet 16 significantly decreases at the position in the plane direction in which the light intensity reduction member 20 is arranged.

However, in the backlight device using the lighting device 10 or the like, generally, a diffusion plate and/or a prism sheet for causing the illuminance of light in the plane direction to be uniform is arranged to correspond to a light exit surface of the lighting device 10. Accordingly, the partial decrease of the illuminance caused by the light intensity reduction member 20 does not cause a problem in practice.

Here, in the lighting device 10 of the present invention, whatever the light intensity reduction member 20 is, in the light intensity reduction member 20, the absorbance of light having a wavelength of 450 nm measured by using an integrating sphere is less than 5%.

In a case where the absorbance of the light at 450 nm by the light intensity reduction member 20 is 5% or more, the light intensity reduction member 20 absorbs light, and the light intensity reduction member 20 is deteriorated according to the absorbed light, heating due to the light absorption, and the like. In a case where the light intensity reduction member 20 is near the wavelength conversion sheet 16 or, particularly, in a case where the light intensity reduction member 20 is in contact with the wavelength conversion sheet 16 as in the illustrated example, the wavelength conversion layer 26 of the wavelength conversion sheet 16 is deteriorated due to the heat of the light intensity reduction member 20.

Considering this point, with respect to the light intensity reduction member 20, the absorbance of the light at a wavelength of 450 nm measured by using the integrating sphere is preferably less than 3% and more preferably less than 1%.

According to the present invention, the absorbance of the light having a wavelength of 450 nm measured by using the integrating sphere by the light intensity reduction member 20 is measured as below.

First, the light intensity reduction member 20 which is a measurement target is cut into a square shape of 2×2 cm and is arranged in the integrating sphere, so as to measure detected light intensity I at 450 nm during incidence of excitation light at 450 nm. As the integrating sphere, an integrating sphere of an absolute PL quantum yield determination device (C9920-02) manufactured by Hamamatsu Photonics K.K. or the like is exemplified.

Otherwise, in the same manner except that the light intensity reduction member 20 is not arranged in the integrating sphere, the detected light intensity I₀ is measured at 450 nm during the incidence of the blank excitation light at 450 nm is measured.

Absorbance A1 of light having a wavelength of 450 nm by the light intensity reduction member 20 as in the following equation by using the detected light intensity I and the blank detected light intensity I₀ in presence of the light intensity reduction member 20 is calculated.

A1=(I₀−I)/I₀

As described above, in the present invention, the area of the light intensity reduction member 20 is not particularly limited. According to the research by the present inventors, the area of the light intensity reduction member 20 is preferably 0.1% to 80% with respect to the area of the light incident surface of the wavelength conversion sheet 16.

In a case where the area of the light intensity reduction member 20 is caused to be 0.1% or more with respect to the area of the light incident surface, the reduction effect of the peak illuminance of the light from the light source 18 on the light incident surface is suitably obtained, so as to suitably prevent the deterioration of the wavelength conversion layer 26 due to light and heat. Otherwise, in a case where the area of the light intensity reduction member 20 is 80% or less with respect to the area of the light incident surface, the excessive reflection and absorption of the light applied by the light source 18 by the light intensity reduction member 20 is prevented such that the lighting device 10 may apply light having sufficient brightness.

Considering the above point, the area of the light intensity reduction member 20 is more preferably 0.3% to 50% and particularly preferably 0.5% to 40% with respect to the area of the light incident surface.

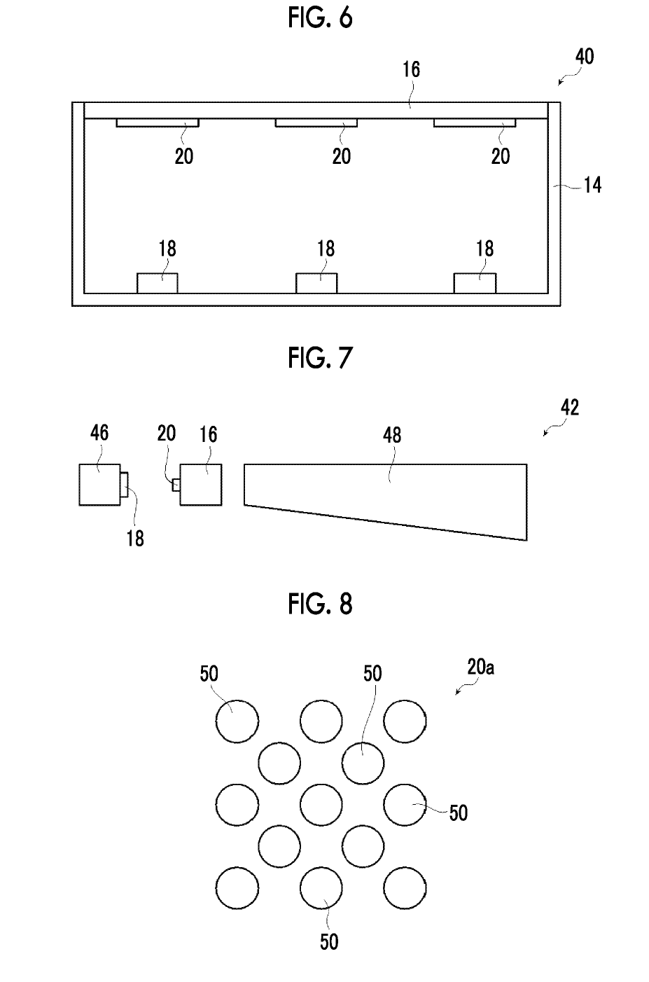

As in the example illustrated in FIG. 6, in a case where the plurality of light intensity reduction members 20 are provided, the area of the light intensity reduction member is a total area of all of the light intensity reduction members 20.

That is, in the example of FIG. 6, the area of the light intensity reduction member is the total area of three of the light intensity reduction members 20.

According to the present invention, the position of the light intensity reduction member 20 in the spacing direction between the light source 18 and the wavelength conversion sheet 16 is not particularly limited. In the above descriptions, the spacing direction between the light source 18 and the wavelength conversion sheet 16 in the lighting device 10 is simply referred to as a “spacing direction”.

Here, according to the research by the present inventors, as illustrated in FIG. 1, the position in the spacing direction of the light intensity reduction member 20 is preferably a position of less than 50% and more preferably a position of less than 30% of the distance between the light intensity reduction member 20 and the wavelength conversion sheet 16 in the spacing direction with respect to the distance L of the spacing direction between the light source 18 and the wavelength conversion sheet 16. That is, the light intensity reduction member 20 is preferably arranged on the wavelength conversion sheet 16 side of the L/2 line illustrated in FIG. 1 in the spacing direction.

Particularly, as in the illustrated example, it is preferable that the light intensity reduction member 20 is provided to be in contact with the wavelength conversion sheet 16.

As described above, the deterioration of the wavelength conversion layer 26 is for causing the light having excessive illuminance to be incident to the wavelength conversion sheet 16. It is preferable that the light source 18 has high directivity. That is, the deterioration of the wavelength conversion layer 26 is mainly caused by the light having the peak illuminance of the light applied by the light source 18.

Therefore, according to the present invention, the peak illuminance of the light applied by the light source 18 on the light incident surface by the light intensity reduction member 20 is reduced by 10% to 80%.

Otherwise, considering the illuminance of the light applied by the lighting device 10, the illuminance of the light incident to the wavelength conversion sheet 16 is preferably high. Therefore, according to the present invention, it is most effective that only the peak illuminance on the light incident surface of the wavelength conversion sheet 16 is reduced by 10% or more.

Here, the light source 18 is a point light source and has high directivity, but applies diffused light.

Therefore, in a case where the light intensity reduction member 20 that reflects and/or absorbs the light from the light source 18 is arranged near the light source 18, in the plane direction, the area applied to the light applied by the light source 18 becomes relatively large, and thus the light other than the region corresponding to the peak illuminance is also reflected and/or absorbed. That is, in a case where the light intensity reduction member 20 is arranged near the light source 18, originally, the light that is not preferably reflected and/or absorbed is also reflected and/or absorbed by the light intensity reduction member 20, the efficiency of using the light decreases, and thus the illuminance of light applied by the lighting device 10 may decrease.

In a case where the light intensity reduction member 20 is arranged near the light source 18, the light is reflected in an unnecessary direction, and is excessively diffused, such that much light proceeds in the unpreferable direction toward the side surface of the housing 14 or the like, and thus the efficiency decreases in this point of view.

In a case where the light intensity reduction member 20 is arranged near the light source 18, the deterioration of the light intensity reduction member 20 due to light and heat easily occurs.

In contrast, the light intensity reduction member 20 may be prevented from acting on an unnecessary region of the light applied by the light source 18 by arranging the light intensity reduction member 20 on the wavelength conversion sheet 16 side of the L/2 line illustrated in FIG. 1. Therefore, the efficiency of using the light may be improved and the illuminance of the light applied by the lighting device 10 may be improved. The deterioration of the light intensity reduction member 20 may be prevented.

Particularly, as in the illustrated example, the light intensity reduction member 20 may be caused to act on the region that needs light applied by the light source 18, such as the optical axis of the light source 18 and the vicinity thereof, by causing the light intensity reduction member 20 to be in contact with the wavelength conversion sheet 16 and to be provided in a layer shape with respect to the light incident surface. As a result, it is possible to increase the illuminance of the light applied by the lighting device 10 by preventing the reflection of unnecessary light or the like and extremely increasing the efficiency of using the light.

It is possible to cause a member supporting the light intensity reduction member 20 in a space between the light source 18 and the wavelength conversion sheet 16 to be unnecessary by causing the light intensity reduction member 20 to be in contact with the wavelength conversion sheet 16 and to be provided in a layer shape on the light incident surface, and thus it is possible to simplify the configuration of the lighting device 10 and further the light intensity reduction member 20 is easily manufactured and arranged.

As described above, the position of the plane direction of the light intensity reduction member 20 is not particularly limited.

Here, the position of the peak illuminance of the light applied by the light source 18 on the light incident surface of the wavelength conversion sheet 16 generally coincide with the optical axis of the light source 18. Accordingly, it is preferable that the light intensity reduction member 20 is arranged at the position including the optical axis of the light source 18 in the plane direction. That is, it is preferable that the light intensity reduction member 20 is arranged at the position intersecting to the optical axis of the light source 18.

The light intensity reduction member 20 may be manufactured by the well-known method according to the forming material.

As in the illustrated example, in a case where the light intensity reduction member 20 is in contact with the wavelength conversion sheet 16 (light incident surface), the light intensity reduction member 20 is manufactured by the well-known film forming method according to the forming material, such as a printing method such as an ink jet method, a coating method using a paint or the like, a vapor phase deposition method such as vapor deposition, and a method of attaching the light intensity reduction member 20 formed in a sheet shape. The manufacturing of the light intensity reduction member 20 by a printing method and a coating method may be performed, for example, by preparing a composition (paint) for forming the light intensity reduction member 20 by using the resin or the particle. The light intensity reduction member 20 formed in a sheet shape is manufactured, for example, by using the composition in the same manner.

In a case where the light intensity reduction member is arranged between the light source 18 and the wavelength conversion sheet 16, a sheet-shaped light intensity reduction member is manufactured by the well-known method according to the forming material, and the light intensity reduction member is stored by the well-known method of storing the sheet-like material, at the intended position.

The shape of the light intensity reduction member 20 may have a suitable shape according to the lighting device 10 and is not particularly limited. For example, in a case where the LED light source is used as the light source 18, the illuminance in the center portion increases, and accordingly the reduction rate of the light intensity (illuminance) in the region corresponding to the center portion (near the optical axis) of the light source 18 in the light intensity reduction member 20 may increase.

The lighting device 10 illustrated in FIG. 1 has only one light source 18 in the direct-type planar lighting device not using a light guide plate, but the present invention is not limited to this.

That is, the present invention may be a direct-type lighting device or may have the plurality of (point) light sources 18 (three light sources in the illustrated example) as in a lighting device 40, as conceptually illustrated in FIG. 6. Here, according to the present invention, in a case where the lighting device has the plurality of light sources 18, generally, as in the lighting device 40 illustrated in FIG. 6, the light intensity reduction members 20 are respectively provided corresponding to the light sources 18.

FIG. 6 is merely a schematic view, and, for example, the lighting device 40 may have various well-known members such as one or more of an LED substrate, wiring, and a heat dissipating mechanism in addition to the members illustrated in the drawing, as in the lighting device 10 illustrated in FIG. 1.

The lighting device 10 illustrated in FIG. 1 and the lighting device 40 illustrated in FIG. 6 are so-called direct-type lighting devices, but the present invention is not limited thereto, and may be suitably used also for a so-called edge light type lighting device using a light guide plate.

An example is illustrated in FIG. 7.

In the lighting device 42 illustrated in FIG. 7, the light source 18 is supported by a supporting member 46 which is long in a direction perpendicular to the paper surface of the drawing. The plurality of light sources 18 are arranged in the longitudinal direction of the supporting member 46, usually at regular intervals. The supporting surface of the light source 18 of the supporting member 46 is preferably a light reflecting surface.

In the lighting device 42, the wavelength conversion sheet 16 is also long in the direction perpendicular to the paper surface. On the light incident surface of the wavelength conversion sheet 16, the plurality of light intensity reduction members 20 are arranged in the longitudinal direction of the wavelength conversion sheet 16 so as to correspond to the respective light sources 18.

A light guide plate 48 is disposed on the light exit surface of the wavelength conversion sheet 16 toward the end face to be the light incident surface.

In the lighting device 42, a portion of the light applied by the light source 18 is reflected and/or absorbed by the light intensity reduction member 20, and the rest thereof is incident to the wavelength conversion sheet 16. The light incident to the wavelength conversion sheet 16 is subjected to wavelength conversion by the wavelength conversion layer 26,exits from the exit surface of the wavelength conversion sheet 16, and is incident to the incident surface of the light guide plate 48.

The light incident to the light guide plate 48 is propagated through the light guide plate 48, is reflected inside the light guide plate 48 and by a reflecting surface (not illustrated) provided in the light guide plate 48, and is applied from the light exit surface on the upper surface of the drawing.

In the above example, the light intensity reduction member 20 includes an integral member that is not divided, that is, one member.

However, according to the present invention, the light intensity reduction member is not limited to a configuration of one integrated member, as long as the peak illuminance on the light incident surface of the light applied by the light source 18 may be reduced by 10% to 80% compared with the case where the light intensity reduction member 20 is not provided, and one light intensity reduction member may be formed by a plurality of divided members.

For example, the light intensity reduction member 20a corresponding to one light source 18 may be formed by forming a plurality of light reflection members 50 as in the light intensity reduction member 20a conceptually illustrated in FIG. 8.

In the above, the lighting device of the present invention is been described, but the present invention is not limited to the above embodiments, and it is obvious that various improvements and modifications may be performed without departing from the gist of the present invention.

### EXAMPLES

Hereinafter, the present invention is specifically described, reference to the specific examples. The present invention is not limited to the examples described below, and a material, an amount used, a treatment detail, a treatment order, and the like provided in the following examples can be appropriately changed without departing from the gist of the present invention.

### Example 1

<Manufacturing of Supporting Film 28>

As the supporting substrate, a PET film (COSMOSHINE A4300 manufactured by Toyobo Co., Ltd., thickness 50 μm) was prepared. A barrier layer was formed on one side of the supporting substrate by the following procedure.

A barrier layer was formed on one side of the supporting substrate by the following procedure.

Trimethylolpropane triacrylate (manufactured by Daicel-Cytec Co., Ltd.) and a photopolymerization initiator (ESACURE KT046 manufactured by Lamberti S.p.A.) were prepared and weighed so as to have the mass ratio of 95:5, and these were dissolved in methyl ethyl ketone, so as to obtain a coating solution having a concentration of solid contents of 15%.

This coating solution was applied to a supporting substrate by roller-to-roller by using a die coater and was caused to pass through a drying zone at 50° C. for three minutes. Thereafter, the coating solution was irradiated with ultraviolet rays in a nitrogen atmosphere (integrating accumulate irradiation amount: about 600 mJ/cm²), and was cured by UV curing so as to form an organic layer, and the organic layer was wound up. The thickness of the organic layer formed on the supporting substrate was 1 μm.

The following description, roller-to-roller is also referred to as “RtoR”.

Subsequently, a silicon nitride layer was formed as an inorganic layer on the surface of the organic layer by using a chemical vapor deposition device (CVD device) by RtoR.

Silane gas (flow rate: 160 sccm), ammonia gas (flow rate: 370 sccm), hydrogen gas (flow rate: 590 sccm), and nitrogen gas (flow rate: 240 sccm) were used as raw material gases. As the power source, a high frequency power source with a frequency of 13.56 MHz was used. Film formation pressure was set to 40 Pa, and the achieved film thickness was set to 50 nm.

In this manner, as the supporting film 28, the lamination type gas barrier film (organic-inorganic lamination type gas barrier film) having an organic layer on the front surface of a supporting substrate including a PET film and having an inorganic layer on the organic layer was manufactured. Two sheets of the supporting films 28 were manufactured.

<Manufacturing Wavelength Conversion Layer 26 (Quantum Dot Layer) and Wavelength Conversion Sheet 16>

The following quantum dot containing polymerizable composition was prepared and filtrated with a polypropylene filter having a pore size of 0.2 μm, and was dried under reduced pressure for 30 minutes, to be used as a coating solution.

In the following, CZ520-100 manufactured by NN-LABS, LLC. was used as the toluene dispersion liquid of the quantum dot 1 having the light emission maximum wavelength of 535 nm. CZ620-100 manufactured by NN-LABS, LLC. was used as the toluene dispersion liquid of the quantum dot 2 having the light emission maximum wavelength of 630 nm.

Both of these were quantum dots using CdSe as a core, ZnS as a shell, and octadecylamine as a ligand, respectively, and were dispersed in toluene at a concentration of 3 mass %.

<<Quantum Dot Containing Polymerizable Composition>>

Toluene dispersion liquid of quantum dot 1 (light emission maximum: 535 nm) 10 parts by mass

Toluene dispersion liquid of quantum dot 2 (light emission maximum: 630 nm) 1 part by mass

Lauryl methacrylate 40 parts by mass

Difunctional methacrylate 4G (manufactured by Shin-Nakamura Chemical Co., Ltd.) 20 parts by mass

Trifunctionalacrylate TMPTA (manufactured by Daicel Corporation) 20 parts by mass

Urethane acrylate UA-160™ (manufactured by Shin-Nakamura Chemical Co., Ltd.) 10 parts by mass

Silane coupling agent KBM-5103 (manufactured by Shin-Etsu Chemical Co., Ltd.) 10 parts by mass

Photopolymerization initiator IRGACURE 819, (manufactured by BASF SE) 1 parts by mass

One sheet of the supporting film 28 manufactured as described above was continuously transported by RtoR at 1 m/min and the tension of 60 N/m in the longitudinal direction and the surface of the inorganic layer was coated with the quantum dot containing polymerizable composition by a die coater, so as to form a coating film having a thickness of 50 μm.

Subsequently, the supporting film 28 on which the coating film was formed was wrapped around a backup roller, another supporting film 28 was laminated on the coating film in a direction in which the inorganic layer was in contact with the coating film, and the coating film was caused to pass through the heating zone at 100° C. for three minutes while continuous transportation was performed in a state in which the coating film was sandwiched between two supporting films 28.

Thereafter, the coating film was cured by being irradiated with ultraviolet rays by using an air cooling metal halide lamp (manufactured by Eye Graphics Co., Ltd.) of 160 W/cm, so as to manufacture the wavelength conversion sheet 16 in which the wavelength conversion layer 26 (quantum dot layer) was sandwiched between two sheets of the supporting films 28. The irradiation amount with ultraviolet rays was 2,000 mJ/cm².

<Light Intensity Reduction Member 20>

A white PET film (MCPET-E3, manufactured by Furukawa Electric Co., Ltd.) having a thickness of 880 μm was cut into 5×5 mm to obtain the light intensity reduction member 20.

<Manufacturing of the Lighting Device 10>

As the housing 14, a rectangular housing having one opening surface of 50×50 mm and having a mirror-finished inner surface was prepared. A blue LED (NSPB346KS manufactured by Nichia Corporation, peak wavelength 450 nm, full width at half maximum of) 55° was fixed as the light source 18 in the center of the bottom surface of the housing 14.

The manufactured wavelength conversion sheet 16 was cut into 50×50 mm. The light intensity reduction member 20 (5×5 mm) was attached to the center of the wavelength conversion sheet 16 by using a pressure sensitive adhesive (highly transparent adhesive transfer tape 8146-2 manufactured by The 3M Company, thickness 50 μm). The area ratio of the light intensity reduction member 20 to the area of the wavelength conversion sheet 16 (light incident surface) was 1%.

The lighting device 10 as illustrated in FIG. 1 was manufactured by closing the open surface of the housing 14 with the wavelength conversion sheet 16 to which the light intensity reduction member 20 was attached. The distance L between the light source 18 and the light incident surface was 4 mm.

<<Measuring Absorbance (Integrated Absorbance) of Light having Wavelength of 450 nm>>

With respect to the light intensity reduction member 20 (white PET film) used in the lighting device 10, the absorbance of light having a wavelength of 450 nm measured using an integrating sphere was measured by the method. The measurement was performed by using an absolute PL quantum yield determination device (C9920-02) manufactured by Hamamatsu Photonics K. K.

As a result, the integrated absorbance of the light intensity reduction member 20 at 450 nm was 0.5%.

<<Measuring of Peak Illuminance Reduction Rate>>

The light source 18 was placed on the base 30 which is the same mirror surface as the bottom surface of the housing 14.

The virtual light incident surface S was set at a position of 4 mm in the perpendicular direction to the base 30 from the light source 18, and the peak illuminance I0max and the peak illuminance I1max were measured by the method, so as to measure the reduction rate of the peak illuminance on the light incident surface by the light intensity reduction member 20. As the illuminance meter 32, VEGA manufactured by OPHIR Optronics Solutions Ltd.

As the film to which the light intensity reduction member 20 was attached and which is arranged on the virtual light incident surface S, a PET film (manufactured by COSMOSHINE A4100 manufactured by Toyobo Co., Ltd., thickness 50 μm) was used.

In the lighting device 10, the attachment of the light intensity reduction member 20 was performed by using the same pressure sensitive adhesive used in the attachment of the light intensity reduction member 20 to the wavelength conversion sheet 16.

As a result, the peak illuminance reduction rate on the light incident surface by the light intensity reduction member 20 was 50%.

### Example 2

The lighting device 10 was manufactured in the same manner as in Example 1 except for changing the light intensity reduction member 20 to a white PET film and using a reflection film having a thickness of 65 μm (ESR manufactured by The 3M Company).

The integrated absorbance and the peak illuminance reduction rate were measured in the same manner as in Example 1. As a result, the integrated absorbance was 2%, and the peak illuminance reduction rate was 45%.

### Example 3

18 g of polymethyl methacrylate (DIANAL BR-85 manufactured by Mitsubishi Rayon Co., Ltd., weight-average molecular weight of 200,000 g/mol) was introduced to a mixed solution of 70 g of methylene chloride and 10.4 g of methanol and stirred for one hour so as to be dissolved.

2 g of titanium oxide (CR-97 manufactured by Ishihara Kogyo Co., Ltd.) having a particle diameter of 0.25 μm was introduced to the mixed solution in which the polymethyl methacrylate resin was dissolved and was further stirred for one hour, so as to obtain a coating solution.

The lighting device 10 was manufactured in the same manner as in Example 1 except for suctioning 0.4 ml of this coating solution with a micropipette, dropwise adding the coating solution in the central part of the wavelength conversion sheet 16, and drying the coating solution at 70° C. for 10 minutes, so as to obtain the light intensity reduction member 20. The light intensity reduction member 20 had a thickness of 12 μm and a circular shape with the size of φ10 mm. The area ratio of the light intensity reduction member 20 with respect to the area of the light incident surface was 3%.

The integrated absorbance and the peak illuminance reduction rate were measured in the same manner as in Example 1. As a result, the integrated absorbance was 1%, and the peak illuminance reduction rate was 40%.

### Example 4

The lighting device 10 was manufactured in the same manner as in Example 3 except for changing the input amount of titanium oxide having a particle diameter of 0.25 μm (CR-97 manufactured by Ishihara Kogyo Co., Ltd.) to 5 g. The light intensity reduction member 20 had a thickness of 20 μm and a circular shape with the size of φ10 mm The area ratio of the light intensity reduction member 20 with respect to the area of the light incident surface was 3%.

The integrated absorbance and the peak illuminance reduction rate were measured in the same manner as in Example 1. As a result, the integrated absorbance was 1%, and the peak illuminance reduction rate was 30%.

### Example 5

0.31g of polymethyl methacrylate (DIANAL BR-88 manufactured by Mitsubishi Rayon Co., Ltd., weight-average molecular weight=1,300,000 g/mol) was introduced to a solvent of 4.18 g of methanol and stirred for 12 hours so as to be dissolved. 2.12 g of an acrylic compound (8BR500 (urethane (meth)acrylate) manufactured by Taisei Fine Chemical Co., Ltd.), 0.4 g of titanium oxide (CR-97 manufactured by Ishihara Kogyo Co., Ltd.) having a particle diameter of 0.25 μm, 2.0 g of methyl ethyl ketone, and 1.0 g of propylene glycol monomethyl ether acetate were introduced to a mixed solution in which a polymethyl methacrylate resin was dissolved, were stirred for one hour so as to obtain a coating solution.

The lighting device 10 was manufactured in the same manner as in Example 1 except for suctioning 0.2 ml of this coating solution with a micropipette, dropwise adding the coating solution in the central part of the wavelength conversion sheet 16, and drying the coating solution at 70° C. for 10 minutes, so as to obtain the light intensity reduction member 20. The light intensity reduction member 20 had a thickness of 17 μm and a circular shape with the size of φ10 mm The area ratio of the light intensity reduction member 20 with respect to the area of the light incident surface was 3%.

The integrated absorbance and the peak illuminance reduction rate were measured in the same manner as in Example 1. As a result, the integrated absorbance was 0.5%, and the peak illuminance reduction rate was 40%.

### Example 6

The lighting device 10 was manufactured in the same manner as in Example 5 except for providing a rectangular frame in the center of the wavelength conversion sheet 16, dropwise adding this coating solution to this frame, and causing the size of the light intensity reduction member 20 to be 14×14 mm The area ratio of the light intensity reduction member 20 with respect to the area of the light incident surface was 8%.

The thickness of the light intensity reduction member 20 was caused to be 17 μm by using the relationship between the coating thickness (coating film thickness) of the coating solution and the thickness of the formed light intensity reduction member 20 which was obtained by an experiment in advance and adjusting the dropwise addition amount (coating thickness) of the coating solution.

The integrated absorbance and the peak light intensity reduction rate were measured in the same manner as in Example 1. As a result, the integrated absorbance was 0.5%, and the peak illuminance reduction rate was 45%.

### Example 7

The lighting device 10 was manufactured in the same method as in Example 5 except for causing the size of the light intensity reduction member 20 to be 22.3×22.3mm and the thickness thereof to be 17 μm. The area ratio of the light intensity reduction member 20 with respect to the area of the light incident surface was 20%.

The integrated absorbance and the peak light intensity reduction rate were measured in the same manner as in Example 1. As a result, the integrated absorbance was 0.5%, and the peak illuminance reduction rate was 60%.

### Example 8

The lighting device 10 was manufactured in the same manner as in Example 1 except for changing the light intensity reduction member 20 to a white PET film using a brightness enhancement film (BEF2-T-155n manufactured by The 3M Company) having a thickness of 155 μm, and causing the size of the light intensity reduction member 20 to 7×7 mm. The area ratio of the light intensity reduction member 20 with respect to the area of the light incident surface was 2%.

The integrated absorbance and the peak illuminance reduction rate were measured in the same manner as in Example 1. As a result, the integrated absorbance was 1%, and the peak illuminance reduction rate was 40%.

### Example 9

The lighting device 10 was manufactured in the same method as in Example 1 except for causing the size of the light intensity reduction member 20 to be 22.3×22.3 mm. The area ratio of the light intensity reduction member 20 with respect to the area of the light incident surface was 20%.

The integrated absorbance and the peak illuminance reduction rate were measured in the same manner as in Example 1. As a result, the integrated absorbance was 0.5%, and the peak illuminance reduction rate was 60%.

### Example 10

The lighting device 10 was manufactured in the same method as in Example 1 except for causing the size of the light intensity reduction member 20 to be 35.4×35.4 mm. The area ratio of the light intensity reduction layer with respect to the area of the light incident surface was 50%.

The integrated absorbance and the peak illuminance reduction rate were measured in the same manner as in Example 1. As a result, the integrated absorbance was 0.5%, and the peak illuminance reduction rate was 70%.

### Example 11

The wavelength conversion sheet 16 was manufactured in the same manner as in Example 1 except for adding 0.4 parts by mass of bis(1,2,2,6,6-pentamethyl-4-piperidyl) sebacate as a hindered amine compound to the quantum dot containing polymerizable composition to be the wavelength conversion layer 26.

The lighting device 10 was manufactured in the same manner as in Example 1 except for using the wavelength conversion sheet 16 and forming the light intensity reduction member 20 in the same manner as in Example 4.

The integrated absorbance and the peak illuminance reduction rate were measured in the same manner as in Example 1. As a result, the integrated absorbance was 1%, and the peak illuminance reduction rate was 30%.

### Example 12

<Manufacturing of Supporting Film 28-2 (Barrier Film with Light Scattering Layer)>

After a protective film (PAC2-30-T manufactured by Sun A. Kaken Co., Ltd.) was bonded to the front surface of the inorganic layer of the supporting film 28 manufactured in advance for protection, and a light scattering layer was formed on the front surface of the PET film on the opposite surface of the inorganic layer by the following method.

<<Preparation of Polymerizable Composition for Forming Light Scattering Layer>>

As the light scattering particle, 150 g of silicone resin particles (TOSPEARL 120 manufactured by Momentive Performance Materials Inc., particle diameter of 2.0 μm) and 40 g of PMMA particles (TECHPOLYMER manufactured by Sekisui Chemical Co., Ltd., particle diameter of 8 μm) were introduced to 550 g of methyl isobutyl ketone (MIBK), were stirred for one hour, and were dispersed, so as to obtain a dispersion liquid.

50 g of an acrylic compound (VISCOAT 700HV, manufactured by Osaka Synthetic Chemical Laboratories, Inc.) and 40 g of an acrylic compound (8BR500 (urethane (meth)acrylate) manufactured by Taisei Fine Chemical Co., Ltd.) were added to the obtained dispersion liquid and were further stirred. 1.5 g of a photopolymerization initiator (IRGACURE (registered trademark) 819 manufactured by BASF SE) and 0.5 g of a fluorine-based surfactant (FC4430, manufactured by The 3M Company) were added so as to manufacture a coating liquid (polymerizable composition for forming a light scattering layer).

<<Coating and Curing Polymerizable Composition for Forming Light Scattering Layer>>

Delivery was set such that the front surface of the PET film of the supporting film 28 to which the protective film was attached was the coated surface, and the PET film of the supporting film 28 was transported to a die coater, and coating was performed. The wet coating amount was adjusted with a liquid delivery pump, and coating was performed at a coating amount of 25 cm³/m². The coating thickness was adjusted such that the thickness of the obtained dry film was about 12 μm. The film was caused to pass through a drying zone at 60° C. for three minutes, was wound around a backup roller of which the temperature was adjusted at 30° C., was cured with ultraviolet rays of 600 mJ/cm², and was wound up. The supporting film 28-2 (barrier film with light scattering layer) was manufactured in this manner.

The wavelength conversion sheet 16-2 was manufactured in the same manner as in Example 1 by using the supporting film 28-2 and sandwiching the wavelength conversion layer 26 between the supporting film 28 and the supporting film 28-2.

The lighting device 10 was manufactured in the same manner as in Example 1 except for using the wavelength conversion sheet 16-2 and forming the light intensity reduction member 20 in the same manner as in Example 4.

The integrated absorbance and the peak illuminance reduction rate were measured in the same manner as in Example 1. As a result, the integrated absorbance was 1%, and the peak illuminance reduction rate was 30%.

### Example 13

The lighting device 10 was manufactured in the same manner as in Example 11 except for changing one sheet of the supporting film 28 to the supporting film 28-2 and using the wavelength conversion sheet 16-2 which is the same as in Example 12.

The integrated absorbance and the peak illuminance reduction rate were measured in the same manner as in Example 1. As a result, the integrated absorbance was 1%, and the peak illuminance reduction rate was 30%.

### Example 14

The lighting device 10 was manufactured in the same manner as in Example 6 except for changing one sheet of the supporting film 28 to the supporting film 28-2 and using the wavelength conversion sheet 16-2 which is the same as in Example 12.

The integrated absorbance and the peak illuminance reduction rate were measured in the same manner as in Example 1. As a result, the integrated absorbance was 0.5%, and the peak illuminance reduction rate was 45%.

### Example 15

The lighting device 10 was manufactured in the same manner as in Example 7 except for changing one sheet of the supporting film 28 to the supporting film 28-2 and using the wavelength conversion sheet 16-2 which is the same as in Example 12.

The integrated absorbance and the peak illuminance reduction rate were measured in the same manner as in Example 1. As a result, the integrated absorbance was 0.5%, and the peak illuminance reduction rate was 60%.

### Comparative Example 1

The lighting device was manufactured in the same method as in Example 1 except for not providing the light intensity reduction member 20.

### Comparative Example 2

As the light scattering particle, 150 g of silicone resin particles (TOSPEARL 120 manufactured by Momentive Performance Materials Inc., particle diameter of 2.0 μm) and 40 g of polymethylmethacrylate particles (TECHPOLYMER manufactured by Sekisui Chemical Co., Ltd., particle diameter of 8 μm) were introduced to 280 g of methyl isobutyl ketone, were stirred for one hour, and were dispersed, so as to obtain a dispersion liquid.

50 g of an acrylic compound (VISCOAT 700HV, manufactured by Osaka Synthetic Chemical Laboratories, Inc.) and 40 g of an acrylic compound (8BR500 (urethane (meth)acrylate) manufactured by Taisei Fine Chemical Co., Ltd.) were added to the obtained dispersion liquid and were stirred for one hour.

1.5 g of a photopolymerization initiator (IRGACURE (registered trademark) 819 manufactured by BASF SE) and 0.5 g of a fluorine-based surfactant (FC4430, manufactured by The 3M Company) were added to the obtained liquid so as to manufacture a coating liquid.

0.1 ml of this coating solution was suctioned with a micropipette, the coating solution was dropwise added in the central part of the wavelength conversion sheet 16. The dropwise added coating solution was dried by being heated at 60° C. for 3 minutes and providing the irradiation effect with ultraviolet rays of 600 mJ/cm² to produce the light intensity reduction member 20.

The lighting device was manufactured in the same manner as in Example 1 except for manufacturing the light intensity reduction member 20 in this manner. The light intensity reduction member had a thickness of 16 μm and a circular shape with the size of φ13 mm The area ratio of the light intensity reduction layer with respect to the area of the light incident surface was 5%.

The integrated absorbance and the peak illuminance reduction rate were measured in the same manner as in Example 1. As a result, the integrated absorbance was 1%, and the peak illuminance reduction rate was 5%.

### Comparative Example 3

The lighting device was manufactured in the same manner as in Example 1 except for causing the size of the light intensity reduction member 20 to be 46×46 mm. The area ratio of the light intensity reduction member 20 with respect to the area of the light incident surface was 85%.

The integrated absorbance and the peak illuminance reduction rate were measured in the same manner as in Example 1. As a result, the integrated absorbance was 0.5%, and the peak illuminance reduction rate was 90%.

### Comparative Example 4

The lighting device was manufactured in the same manner as in Example 1 except for changing the light intensity reduction member 20 to a white PET film and using a copper film (PNS H manufactured by Arisawa Manufacturing Co., Ltd.) having a thickness 40 μm and a size of 11×11 mm. The area ratio of the light intensity reduction member 20 with respect to the area of the light incident surface was 5%.

The integrated absorbance and the peak illuminance reduction rate were measured in the same manner as in Example 1. As a result, the integrated absorbance was 10%, and the peak illuminance reduction rate was 30%.

With respect to lighting devices of Examples 1 to 15 and Comparative Examples 1 to 4 manufactured in this manner, the brightness and the durability were measured, and the comprehensive evaluation was performed.

[Measuring of Brightness]

Two sheets of prism sheets and light diffusion plates were arranged on the front surface of light exit surface of the lighting device 10. The prism sheet was disposed such that the ridgelines of the prism were orthogonal.

Brightness meters (SR3 manufactured by Topcon Positioning Systems, Inc.) were provided in the center of the light exit surface of the lighting device 10 and at the position of 740 mm from light exit surface in the perpendicular direction.

The lighting device 10 was turned on, and the brightness was measured by the provided brightness meters after one hour.

Results thereof are as presented in Table 1. The measurement result of the brightness is referred to as a value standardized with the measurement result of Comparative Example 1 as 1.

[Measurement of Durability]

The measured value of the measurement result of the brightness was set as the initial brightness L0.

The lighting device 10 was turned on for 1,000 hours without change, and the brightness was measured in the same manner, so as to obtain the post-test brightness L1.

From the initial brightness LO and the post-test brightness L1, the durability [%]was evaluated according to the following equation.

Durability [%]=(L1/L0)×100

Results thereof are also presented in Table 1.

[Comprehensive Evaluation]

According to the evaluation results of the brightness and the durability, comprehensive evaluation was performed in the following standards. Even in a case of Comprehensive Evaluation 2, there is no problem in practice.

Comprehensive Evaluation 1: Those satisfying both of the brightness of 0.8 or more and the durability of 75% or more

Comprehensive Evaluation 2: Those which satisfy both of the brightness of 0.7 or more and the durability of 60% or more and are not Comprehensive Evaluation 1

Comprehensive Evaluation 3: Those which satisfy none of the brightness of 0.7 or more and the durability of 60% or more

Results thereof are also presented in Table 1.

TABLE 1

| | Light intensity reduction member | | | | | | | |
|---|---|---|---|---|---|---|---|---|
| | | | | Illuminance | | | | |
| | | | Area | reduction | Integrated | Evaluation | | |
| | | Optical | ratio | rate | absorbance | Backlight | Durability | Comprehensive |
| | Material | action | [%] | [%] | [%] | brightness | [%] | evaluation |
| Example 1 | White PET | Scattering | 1 | 50 | 0.5 | 0.9 | 95 | 1 |
| Example 2 | Reflection film | Interference | 1 | 45 | 2 | 0.85 | 85 | 1 |
| | | reflection | | | | | | |
| Example 3 | Fine particle scattering layer | Scattering | 3 | 40 | 1 | 0.95 | 80 | 1 |
| Example 4 | Fine particle scattering layer | Scattering | 3 | 30 | 1 | 0.95 | 70 | 2 |
| Example 5 | Fine particle scattering layer | Scattering | 3 | 40 | 0.5 | 0.96 | 80 | 1 |
| Example 6 | Fine particle scattering layer | Scattering | 8 | 45 | 0.5 | 0.85 | 85 | 2 |
| Example 7 | Fine particle scattering layer | Scattering | 20 | 60 | 0.5 | 0.9 | 97 | 2 |
| Example 8 | Enhancement film | Refraction | 3 | 40 | 1 | 0.9 | 80 | 1 |
| Example 9 | White PET | Scattering | 20 | 60 | 0.5 | 0.78 | 97 | 2 |
| Example 10 | White PET | Scattering | 50 | 70 | 0.5 | 0.7 | 98 | 2 |
| Example 11 | Fine particle scattering layer | Scattering | 3 | 30 | 1 | 0.95 | 99 | 1 |
| Example 12 | Fine particle scattering layer | Scattering | 3 | 30 | 1 | 1.05 | 100 | 1 |
| Example 13 | Fine particle scattering layer | Scattering | 3 | 30 | 1 | 1.05 | 101 | 1 |
| Example 14 | Fine particle scattering layer | Scattering | 8 | 45 | 0.5 | 10.7 | 100 | 1 |
| Example 15 | Fine particle scattering layer | Scattering | 20 | 60 | 0.5 | 1.06 | 100 | 1 |
| Comparative | None | — | — | — | — | 1 | 30 | 3 |
| Example 1 | | | | | | | | |
| Comparative | Scattering layer | Scattering | 5 | 5 | 1 | 1 | 45 | 3 |
| Example 2 | | | | | | | | |
| Comparative | White PET | Scattering | 85 | 90 | 0.5 | 0.1 | 95 | 3 |
| Example 3 | | | | | | | | |
| Comparative | Copper film | Mirror surface | 5 | 30 | 10 | 0.9 | 50 | 3 |
| Example 4 | | reflection | | | | | | |

Enhancement film in Example 5 refers to a light enhancement film.
In Example 8, a wavelength conversion layer of a wavelength conversion sheet includes a hindered amine compound.
In Examples 12 to 15, a wavelength conversion sheet uses a barrier film and a barrier film with a light scattering layer.

As illustrated in Table 1, the lighting device 10 of the present invention has almost the same brightness as Comparative Example 1 not having the light intensity reduction member 20 and also having excellent durability.

In contrast, since the lighting device of Comparative Example 1 does not have the light intensity reduction member 20, the lighting device of Comparative Example 2 has extremely low reduction rate of the peak illuminance by the light intensity reduction member 20 and also has high brightness, but the wavelength conversion sheet 16 (the wavelength conversion layer 26) is deteriorated due to light and heat of the light source 18 and thus has deteriorated durability.

The lighting device of Comparative Example 3 has an extremely high reduction rate of the peak illuminance by the light intensity reduction member 20 and thus has extremely low backlight brightness.

The lighting device of Comparative Example 4 has extremely high integrated absorbance of the light intensity reduction member 20, the light intensity reduction member 20 generates heat and is deteriorated, and accordingly the wavelength conversion sheet 16 (the wavelength conversion layer 26) is deteriorated and has deteriorated durability.

According to the above results, the effect of the present invention is clear.

It may be suitably used as illumination light sources of various devices such as an LCD backlight.

### EXPLANATION OF REFERENCES

10, 40, 42: lighting device

14: housing

16: wavelength conversion sheet

18: (point) light source

20, 20a: light intensity reduction member

26: wavelength conversion layer

28: supporting film

30: base

32: illuminance meter

32a: sensor

34: light screen

34a: through-hole

46: supporting member

48: light guide plate

50: light reflection member

S: virtual light incident surface

What is claimed is:

1. A lighting device comprising:
one or more point light source;
a wavelength conversion member; and
one or more light intensity reduction members arranged between the point light source and the wavelength conversion member,
wherein the light intensity reduction member reduces peak illuminance of light that is applied by the point light source on a light incident surface of the wavelength conversion member by 10% to 80%, and absorbance of light having a wavelength of 450 nm measured by using an integrating sphere is less than 5%.

2. The lighting device according to claim 1,
wherein the light intensity reduction member reduces illuminance of light incident on the wavelength conversion member by diffusion or total surface reflection.

3. The lighting device according to claim 1,
wherein a total area of the light intensity reduction member is 0.1% to 80% of an area of the light incident surface of the wavelength conversion member.

4. The lighting device according to claim 1,
wherein a distance between the wavelength conversion member and the light intensity reduction member is less than 50% of a distance between the point light source and the wavelength conversion member.

5. The lighting device according to claim 4,
wherein the light intensity reduction member is in contact with the wavelength conversion member.

6. The lighting device according to claim 1,
wherein the point light source is a blue light emitting diode.

7. The lighting device according to claim 1, further comprising:
a light reflecting surface aside of the point light source opposite to the light intensity reduction member.
